(19) United States
(12) Patent Application Publication
(10) Pub. No.: US 2026/0122877 A1
(43) Pub. Date: Apr. 30, 2026

(54) SEMICONDUCTOR MEMORY DEVICE

(71) Applicant: Samsung Electronics Co., Ltd., Suwon-si (KR)

(72) Inventors: Jun Hee PARK, Suwon-si (KR); Ho Jun KWON, Suwon-si (KR); Nam-Gun KIM, Suwon-si (KR)

(21) Appl. No.: 19/223,199

(22) Filed: May 30, 2025

(30) Foreign Application Priority Data
Oct. 31, 2024 (KR) 10-2024-0152538

(51) Int. Cl. H10B 12/00

(52) U.S. Cl. CPC H10B 12/315; H10B 12/0335; H10B 12/50

(57) ABSTRACT

The semiconductor memory device includes a substrate including an active area, a bit line structure on the substrate, the bit line structure including a cell conductive line and a cell line capping film, storage contacts disposed on opposing sides of the bit line structure and connected to the active area, a storage pad on one of the storage contacts and connected to one of the storage contacts, and a data storage pattern on an upper surface of the cell line capping film and connected to the storage pad, and wherein the storage pad includes an upper storage pad, and a lower storage pad disposed between the upper storage pad and the storage contact, and wherein a width of the upper storage pad disposed on top of the upper surface of the cell line capping film increases with distance from the upper surface of the cell line capping film.

### CROSS-REFERENCE TO RELATED APPLICATION

This application claims priority from Korean Patent Application No. 10-2024-0152538 filed on Oct. 31, 2024 in the Korean Intellectual Property Office, and all the benefits accruing therefrom under 35 U.S.C. 119, the contents of which is incorporated by reference for all purposes as if fully set forth herein in its entirety.

### FIELD

The present disclosure relates to a semiconductor memory device, and more specifically, to a semiconductor memory device having multiple wiring lines intersecting with each other, and buried contacts.

### BACKGROUND

As a semiconductor device becomes increasingly highly integrated, individual circuit patterns are becoming smaller in order to implement a larger number of semiconductor devices in the same area. That is, as integration of the semiconductor device increases, a design rule for individual components of the semiconductor device decreases.

In a highly scaled semiconductor device, a process of forming a plurality of wiring lines and a plurality of buried contacts (BC) interposed therebetween may become increasingly complicated and sophisticated.

### SUMMARY

Aspects of the present disclosure provide a semiconductor memory device having improved reliability and performance.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, there is provided a semiconductor memory device comprising, a substrate including an active area bounded by an element isolation film, a bit line structure on the substrate, the bit line structure including a cell conductive line and a cell line capping film, wherein the cell line capping film extends along and on an upper surface of the cell conductive line, storage contacts on opposing sides of the bit line structure and connected to the active area, a storage pad on one of the storage contacts and connected to one of the storage contacts, and a data storage pattern on an upper surface of the cell line capping film and connected to the storage pad, and wherein the storage pad includes an upper storage pad, and a lower storage pad disposed between the upper storage pad and the storage contact, and wherein a width of the upper storage pad on top of the upper surface of the cell line capping film increases with distance from the upper surface of the cell line capping film.

According to an embodiment of the present disclosure, there is provided a semiconductor memory device comprising, a substrate including an active area bounded by an element isolation film, a bit line structure on the substrate and including a cell conductive line and a cell line capping film stacked in a first direction, wherein the cell line capping film extends along and on an upper surface of the cell conductive line, storage contacts on opposing sides of the bit line structure and connected to the active area, a storage pad on one of the storage contacts and connected to one of the storage contacts, and a data storage pattern on an upper surface of the cell line capping film, and connected to the storage pad, wherein the storage pad includes an upper storage pad, and a lower storage pad between the upper storage pad and the storage contact, wherein the upper storage pad includes an upper surface connected to the data storage pattern, a bottom surface in contact with the lower storage pad and the bit line structure, and a sidewall connecting the upper surface of the upper storage pad and the bottom surface of the upper storage pad to each other, wherein the upper storage pad includes an upper pad filling film, and an upper pad silicide film, and wherein the upper pad silicide film includes the sidewall of the upper storage pad.

According to an embodiment of the present disclosure, there is provided a semiconductor memory device comprising, a substrate including a cell area and a peripheral area around the cell area, the cell area including a cell active area bounded by a cell element isolation film, a bit line structure on the cell area of the substrate and including a cell conductive line and a cell line capping film, wherein the cell line capping film extends along and on an upper surface of the cell conductive line, a peripheral gate structure on the peripheral area of the substrate and including a peripheral gate conductive film, peripheral wiring lines on the peripheral gate structure, storage contacts connected to the cell active area, storage pads connected to the storage contacts, a pad isolation pattern isolating adjacent ones of the storage pads from each other, and data storage patterns on an upper surface of the cell line capping film and connected to the storage pad, wherein the storage pads include an upper storage pad and a lower storage pad disposed between the upper storage pad and the storage contact, wherein the upper storage pad includes a first portion disposed on the upper surface of the cell line capping film and a second portion between the first portion of the upper storage pad and the lower storage pad, and wherein a width of the first portion of the upper storage pad increases with distance from the upper surface of the cell line capping film.

It should be noted that the effects of the present disclosure are not limited to those described above, and other effects of the present disclosure will be apparent from the following description.

### BRIEF DESCRIPTION OF DRAWINGS

The above and other features of the present disclosure will become more apparent by describing in detail some embodiments thereof with reference to the attached drawings listed below.

FIG. 1 is a schematic layout diagram of a semiconductor memory device according to some embodiments.

FIG. 2 is a layout diagram of an area R as a portion of a cell area in FIG. 1.

FIG. 3 is a layout diagram showing only word-lines and active areas of FIG. 2.

FIG. 4 is a cross-sectional view taken along a line A-A in FIG. 1.

FIG. 5 and FIG. 6 are cross-sectional views taken along lines B-B and C-C of FIG. 2, respectively.

FIG. 7 is an enlarged view of a portion P of FIG. 4.

FIG. 8 is an enlarged view of a portion Q of FIG. 5.

FIG. 9 and FIG. 10 are diagrams for illustrating a semiconductor memory device according to some embodiments.

FIG. 11 and FIG. 12 are diagrams for illustrating a semiconductor memory device according to some embodiments.

FIGS. 13 to 15 are diagrams for illustrating a semiconductor memory device according to some embodiments.

FIG. 16 and FIG. 17 are diagrams for illustrating a semiconductor memory device according to some embodiments.

FIGS. 18 to 20 are diagrams for illustrating a semiconductor memory device according to some embodiments.

FIG. 21 and FIG. 22 are diagrams for illustrating a semiconductor memory device according to some embodiments.

FIG. 23 and FIG. 24 are diagrams for illustrating a semiconductor memory device according to some embodiments.

FIG. 25 is a diagram for illustrating a semiconductor memory device according to some embodiments.

FIGS. 26 to 31 are diagrams of intermediate structures corresponding to intermediate steps of a method for manufacturing a semiconductor memory device according to some embodiments.

FIGS. 32 to 36 are diagrams of intermediate structures corresponding to intermediate steps for of a method for manufacturing a semiconductor memory device according to some embodiments.

### DETAILED DESCRIPTION OF EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

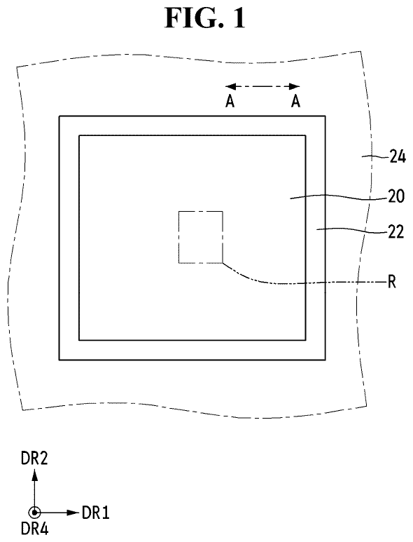

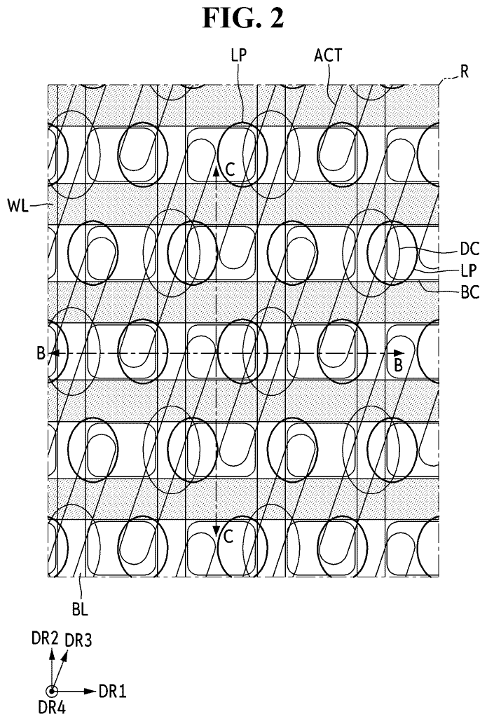

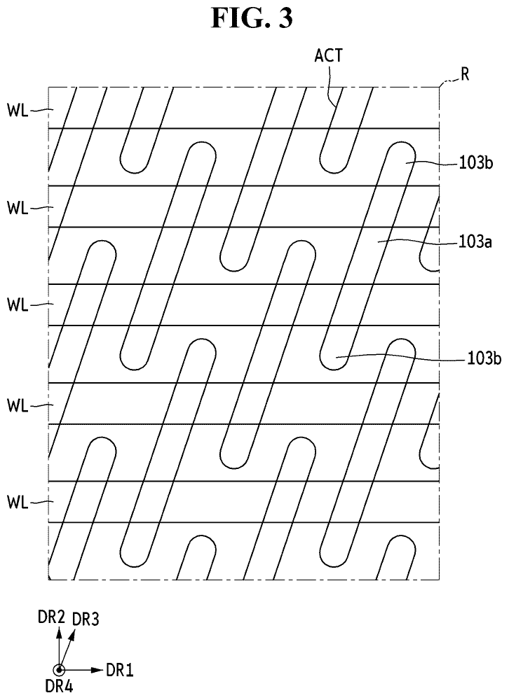

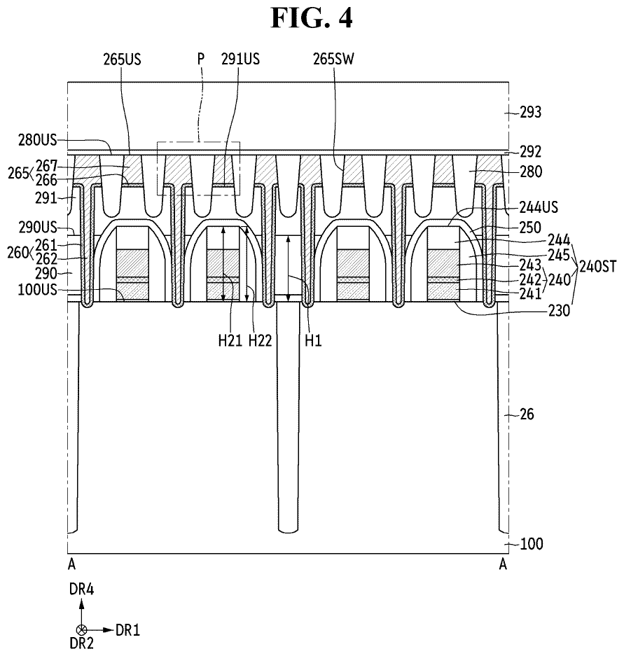

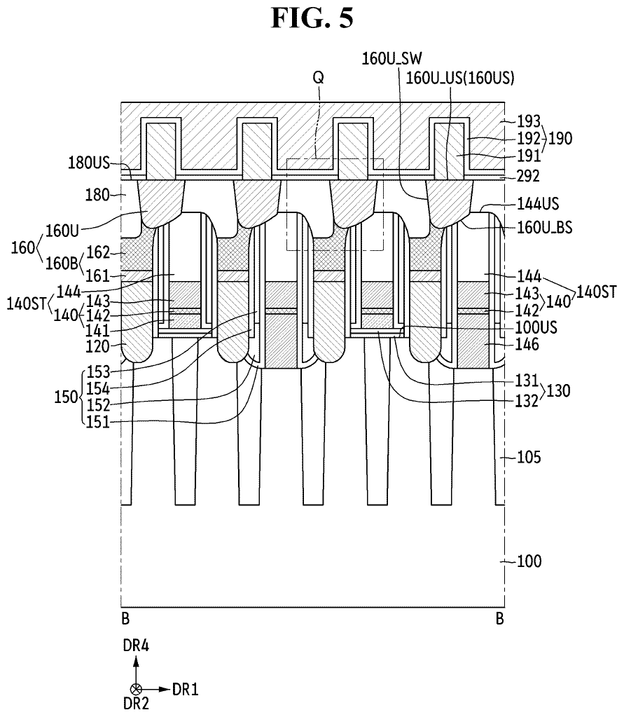

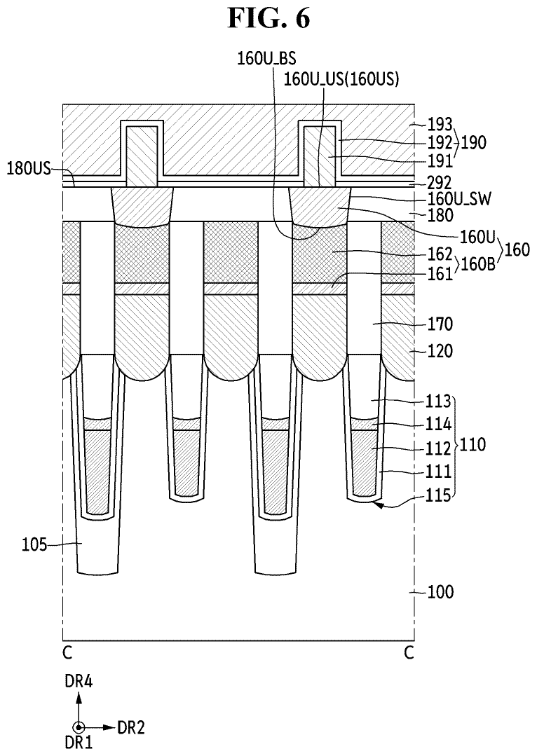

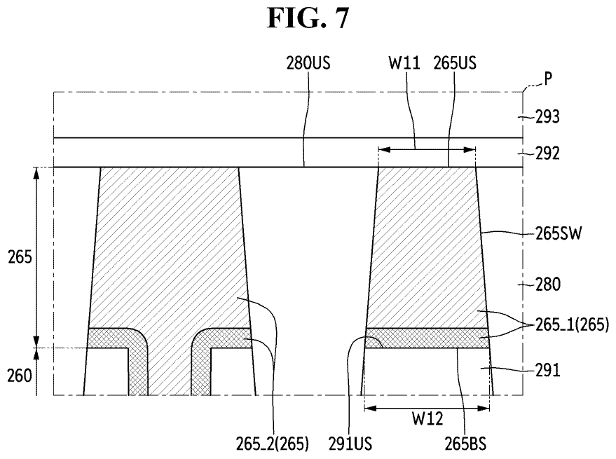

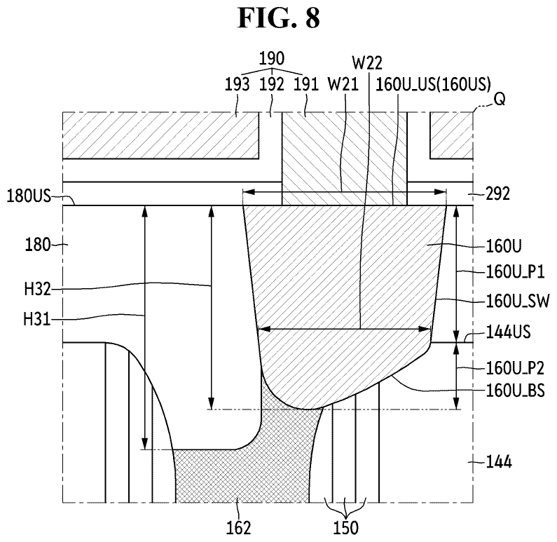

FIG. 1 is a schematic layout diagram of a semiconductor memory device according to some embodiments. FIG. 2 is a layout diagram of an area R as a portion of a cell area in FIG. 1. FIG. 3 is a layout diagram showing only a word-line and an active area of FIG. 2. FIG. 4 is a cross-sectional view cut along a line A-A in FIG. 1. FIG. 5 and FIG. 6 are cross-sectional views taken along lines B-B and C-C of FIG. 2, respectively. FIG. 7 is an enlarged view of a portion P of FIG. 4. FIG. 8 is an enlarged view of a portion Q of FIG. 5.

For reference, FIG. 4 may be an illustrative cross-sectional view of a transistor formation area in a peripheral area. In FIG. 1, the cutting line A-A is shown as extending along a first direction DR1. However, embodiments of the present disclosure are not limited thereto. Unlike what is shown, the cutting line A-A may extend along a second direction DR2.

In the drawing of the semiconductor memory device according to some embodiments, a Dynamic Random Access Memory DRAM is shown by way example. However, embodiments of the present disclosure are not limited thereto.

Referring to FIG. 1 to FIG. 3, the semiconductor memory device according to some embodiments may include a cell area 20, the cell area isolation film 22, and a peripheral area 24.

The cell area isolation film 22 may be disposed around the cell area 20. The cell area isolation film 22 may isolate the cell area 20 and the peripheral area 24 from each other. The peripheral area 24 may be defined around the cell area 20.

The cell area 20 may include a plurality of the cell active areas ACT. The cell active area ACT may be defined by a cell element isolation film (105 of FIG. 5) formed in a substrate (100 of FIG. 5). As a design rule of a semiconductor memory device decreases, the cell active area ACT may extend in a bar shape along a diagonal line or an oblique line. For example, the cell active area ACT may extend in a third direction DR3.

A plurality of gate electrodes may extend in a first direction DR1 and across the cell active area ACT. The plurality of gate electrodes may extend in a parallel manner to each other. The plurality of gate electrodes may be, for example, a plurality of word-lines WL. The word-line WL may be arranged to be spaced from each other at an equal spacing. A width of the word-line WL or the spacing between the word-lines WL may be determined based on the design rule.

Two word-lines WL extending in the first direction DR1 may divide each cell active area ACT into 3 portions. The cell active area ACT may include a bit-line connection area 103a and a storage connection area 103b. The bit-line connection area 103a may be located in a middle portion of the cell active area ACT, and the storage connection area 103b may be located at an end of the cell active area ACT.

A plurality of bit-lines BL extending in a second direction DR2 and orthogonal to the word-line WL may be disposed on the word-line WL. In other embodiments, the plurality of bit-lines BL may intersect with the word-line WL and not necessarily be orthogonal. The plurality of bit-lines BL may extend in a parallel manner to each other. The bit-lines BL may be arranged to be spaced apart from each other at an equal spacing or with variable spacing. A width of the bit-line BL or the spacing between the bit-lines BL may be determined based on the design rule.

The semiconductor memory device according to some embodiments may include various contact arrays formed on the cell active area ACT. The various contact arrangements may include, for example, a direct contact (DC), a buried contact (BC), and a landing pad (LP).

In this regard, the direct contact DC may mean a contact electrically connecting the cell active area ACT to the bit-line BL. The buried contact BC may mean a contact that connects the cell active area ACT to a lower electrode (191 of FIG. 5) of a data storage pattern. Due to a layout structure, a contact area between the buried contact BC and the cell active area ACT may be small. Accordingly, in order to increase the contact area between the buried contact BC and the cell active area ACT and a contact area between the buried contact BC and the lower electrode (191 of FIG. 5) of the data storage pattern, a conductive landing pad LP may be introduced.

The landing pad LP may be disposed between the buried contact BC and the lower electrode (191 of FIG. 5) of the data storage pattern and may be disposed between the cell active area ACT and the buried contact BC. In the semiconductor memory device according to some embodiments, the landing pad LP may be disposed between the buried contact BC and the lower electrode (191 of FIG. 5) of the data storage pattern. The contact area may increase due to the introduction of the landing pad LP, such that a contact resistance between the cell active area ACT and the lower electrode (191 of FIG. 5) of the data storage pattern may be reduced.

The direct contact DC may be connected to the bit-line connection area 103a. The buried contact BC may be connected to the storage connection area 103b. As the buried contact BC is disposed at each of both opposing ends of the cell active area ACT, the landing pad LP may be disposed adjacent to each of both opposing ends of the cell active area ACT so as to partially overlap the buried contact BC. In other words, the buried contact BC may be formed to overlap a portion of each of the cell active area ACT and the cell element isolation film (105 of FIG. 5) disposed between adjacent word-lines WL and between adjacent bit-lines BL.

The word-line WL may be formed as a structure buried in the substrate 100. The word-line WL may extend across a portion of the cell active area ACT disposed between the direct contacts DC or the buried contacts BC. As shown, two word-lines WL may intersect one cell active area ACT. As the cell active area ACT extends along the third direction DR3, the word-line WL may define an angle smaller than 90 degrees relative to the cell active area ACT.

The direct contacts DC may be arranged symmetrically. The buried contacts BC may be arranged symmetrically. Thus, the direct contacts DC may be arranged in a straight line along each of the first direction DR1 and the second direction DR2. The buried contacts BC may be arranged in a straight line along each of the first direction DR1 and the second direction DR2.

Unlike the direct contact DC and the buried contact BC, the landing pads LP associated with each cell active area ACT may be arranged in a zigzag pattern along the second direction DR2 in which the bit-line BL extends. Further, the landing pads LP may respectively overlap the same side surface of the bit-lines BL arranged in the first direction DR1 in which the word-line WL extends.

For example, the landing pads LP of a first line may respectively overlap left side surface of corresponding bit-lines BL, while the landing pads LP of a second line may respectively overlap right side surface of corresponding bit-lines BL.

Referring to FIG. 1 to FIG. 8, the semiconductor memory device according to some embodiments may include a plurality of the cell gate structures 110, a plurality of bit-line structures 140ST, a plurality of storage contacts 120, a plurality of storage pads 160, a data storage pattern 190, a peripheral gate structure 240ST, and a peripheral wiring line 265.

The substrate 100 may include the cell area 20, the cell area isolation film 22, and the peripheral area 24. The substrate 100 may be a silicon substrate or an SOI (silicon-on-insulator) substrate. Alternatively, the substrate 100 may include, but is not limited to, silicon germanium, SGOI (silicon germanium on insulator), indium antimonide, a lead telluride compound, indium arsenide, indium phosphide, gallium arsenide, or gallium antimonide.

The plurality of the cell gate structures 110, the plurality of bit-line structures 140ST, the plurality of storage contacts 120, the plurality of storage pads 160, and the data storage pattern 190 may be disposed in the cell area 20. The peripheral gate structure 240ST, and the peripheral wiring line 265 may be disposed in the peripheral area 24.

The cell element isolation film 105 may be formed in the substrate 100 and in the cell area 20. The cell element isolation film 105 may have an STI (shallow trench isolation) structure having excellent element isolation ability. The cell element isolation film 105 may define the cell active area ACT in the cell area 20. As shown in FIG. 2 and FIG. 3, the cell active area ACT defined by the cell element isolation film 105 may have an elongate island shape including a short side and a long side. The cell active area ACT may extend in the diagonal shape so as to define an angle smaller than 90 degrees with respect to the word-line WL formed in the cell element isolation film 105. Further, the cell active area ACT may extend in the diagonal shape to define an angle smaller than 90 degrees with respect to the bit-line BL disposed on the cell element isolation film 105.

The cell area isolation film 22 may have a cell boundary isolation film having an STI structure. The cell area 20 may be defined by the cell area isolation film 22.

Each of the cell element isolation film 105 and the cell area isolation film 22 may include, for example, one of a silicon oxide film, a silicon nitride film, and a silicon oxynitride film. However, embodiments of the present disclosure are not limited thereto. In FIG. 5 and FIG. 6, the cell element isolation film 105 is illustrated as one insulating film. However, this is intended only for convenience of illustration, and embodiments of the present disclosure are not limited thereto. Depending on a width of each of the cell element isolation film 105 and the cell area isolation film 22, each of the cell element isolation film 105 and the cell area isolation film 22 may be formed as one insulating film, or may be formed as a stack of a plurality of insulating films.

In FIG. 5, it is illustrated that an upper surface of the cell element isolation film 105 and an upper surface of the substrate 100 are coplanar with each other. However, this is intended only for convenience of illustration, and embodiments of the present disclosure are not limited thereto.

As illustrated in FIG. 6, the cell gate structure 110 may be disposed in the substrate 100 and the cell element isolation film 105. The cell gate structure 110 may extend across the cell element isolation film 105 and the cell active area ACT defined by the cell element isolation film 105. The cell gate structure 110 may include a cell gate trench 115 formed in the substrate 100 and the cell element isolation film 105, a cell gate insulating film 111, a cell gate electrode 112, a cell gate capping pattern 113, and a cell gate capping conductive film 114. In this regard, the cell gate electrode 112 may correspond to the word-line WL in FIG. 2. Unlike what is illustrated, for the word-line WL the cell gate structure 110 may not include the cell gate capping conductive film 114.

The cell gate trench 115 may be relatively deep within the cell element isolation film 105 and may be relatively shallow within the cell active areas ACT That is, the depth of the cell gate trench 115 in the cell element isolation film 105 may be greater than the depth of the cell gate trench 115 in the cell active area ACT. A bottom surface of the cell gate electrode 112 may be curved.

The cell gate insulating film 111 may extend along a sidewall and a bottom face of the cell gate trench 115. The cell gate insulating film 111 may extend along a profile of at least a portion of the cell gate trench 115. The cell gate insulating film 111 may include, for example, one of silicon oxide, silicon nitride, silicon oxynitride, or a high dielectric constant material having a higher dielectric constant than that of silicon oxide. The high dielectric constant material may include, for example, one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, embodiments of the present disclosure are not limited thereto.

The cell gate electrode 112 may be disposed on the cell gate insulating film 111. The cell gate electrode 112 may fill a portion of the cell gate trench 115. The cell gate capping conductive film 114 may extend along an upper surface of the cell gate electrode 112.

The cell gate electrode 112 may include at least one of a metal, a conductive metal nitride, a conductive metal carbonitride, a conductive metal carbide, a metal silicide, a doped semiconductor material, a conductive metal oxynitride, or a conductive metal oxide. The cell gate electrode 112 may include, for example, one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrOₓ, RuOₓ, or combinations thereof. However, embodiments of the present disclosure are not limited thereto. The cell gate capping conductive film 114 may include, for example, polysilicon or polysilicon germanium. However, embodiments of the present disclosure are not limited thereto.

The cell gate capping pattern 113 may be disposed on the cell gate electrode 112 and the cell gate capping conductive film 114. The cell gate capping pattern 113 may fill a portion of the cell gate trench 115 remaining after the cell gate electrode 112 and the cell gate capping conductive film 114 have been formed in the cell gate trench 115. Although the cell gate insulating film 111 is illustrated as extending along a sidewall of the cell gate capping pattern 113, embodiments of the present disclosure are not limited thereto.

The cell gate capping pattern 113 may include, for example, one of silicon nitride (SiN), silicon oxynitride (SiON), silicon oxide (SiO₂), silicon carbonitride (SiCN), silicon oxycarbonitride (SiOCN), or combinations thereof.

Although not shown, an impurity doped area may be formed on at least one side of the cell gate structure 110. The impurity doped area may be a source/drain area of a transistor.

The bit-line structure 140ST may include a cell conductive line 140 and a cell line capping film 144. The cell conductive line 140 may be disposed on a portion of each of the substrate 100 and the cell element isolation film 105 on which the cell gate structure 110 has been disposed.

The cell conductive line 140 may extend in the second direction DR2. The cell conductive line 140 may intersect the cell element isolation film 105 and the cell active area ACT defined by the cell element isolation film 105. The cell conductive line 140 may be formed to intersect the cell gate structure 110. In this regard, the cell conductive line 140 may correspond to the bit-line BL in FIG. 2.

The cell conductive line 140 may be a stack of multiple films. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the cell element isolation film 105 in a fourth direction DR4. Although the cell conductive line 140 is illustrated as the stack of three films, embodiments of the present disclosure are not limited thereto.

Each of the first to third cell conductive films 141, 142, and 143 may include, for example, at least one of semiconductor material doped with impurities, a conductive metal nitride, a conductive metal carbonitride, a conductive metal carbide, a metal silicide, a conductive metal oxynitride, a conductive metal oxide, a two-dimensional (2D) material, or a metal. In the semiconductor memory device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂ ), molybdenum diselenide (MoSe₂ ), tungsten diselenide (WSe₂ ), and tungsten disulfide (WS₂ ). However, the present disclosure is not limited thereto. In other words, the above-described two-dimensional materials are listed only by way of example. The two-dimensional material that may be included in the semiconductor memory device of the present disclosure is not limited to the above-described materials.

For example, the first cell conductive film 141 may include a doped semiconductor material, the second cell conductive film 142 may include at least one of a conductive silicide compound, a conductive metal nitride, or a two-dimensional material, and the third cell conductive film 143 may include metal. However, embodiments of the present disclosure are not limited thereto.

The bit-line contact 146 may be disposed between the cell conductive line 140 and the substrate 100. That is, the cell conductive line 140 may be disposed on the bit-line contact 146. For example, the bit-line contact 146 may be disposed at a point where the cell conductive line 140 intersects the middle portion of the cell active area ACT having the elongate island shape. The bit-line contact 146 may be disposed between the bit-line connection area 103a and the cell conductive line 140.

The bit-line contact 146 may electrically connect the cell conductive line 140 and the substrate 100 to each other. In this regard, the bit-line contact 146 may correspond to the direct contact DC in FIG. 2. The bit line contact 146 may include, for example, at least one of a semiconductor material doped with an impurity, a conductive metal nitride, a conductive metal carbonitride, a conductive metal carbide, a metal silicide, a conductive metal oxynitride, a conductive metal oxide, or a metal.

In FIG. 5, in an area overlapping an upper surface of the bit-line contact 146, the cell conductive line 140 may include the second cell conductive film 142 and the third cell conductive film 143. In an area that does not overlap with the upper surface of the bit-line contact 146, the cell conductive line 140 may include the first to third cell conductive films 141, 142, and 143. A thickness of a portion of the cell conductive line 140 in the area overlapping with the upper surface of the bit-line contact 146 may be different from a thickness of a portion of the cell conductive line 140 in the area non-overlapping with the upper surface of the bit-line contact 146.

The cell line capping film 144 may be disposed on the cell conductive line 140. The cell line capping film 144 may extend in the second direction DR2 and along an upper surface of the cell conductive line 140. In this regard, the cell line capping film 144 may include, for example, at least one of silicon nitride, silicon oxynitride, silicon carbonitride, or silicon oxycarbonitride. In the semiconductor memory device according to some embodiments, the cell line capping film 144 may include, for example, silicon nitride. Although the cell line capping film 144 is illustrated as a single film, embodiments of the present disclosure are not limited thereto. In other words, the cell line capping film 144 may be a stack of multi-films. However, when the films constituting the stack are made of the same material, the cell line capping film 144 may be considered as a single film.

The cell insulating film 130 may be disposed on the substrate 100 and the cell element isolation film 105. More specifically, the cell insulating film 130 may be formed on a portion of each of the substrate 100 and the cell element isolation film 105 on which the bit-line contact 146 is not disposed. The cell insulating film 130 may be disposed between the substrate 100 and the cell conductive line 140 and between the cell element isolation film 105 and the cell conductive line 140.

It is illustrated that the cell insulating film 130 may be a stack of a first cell insulating film 131 and a second cell insulating film 132. However, the cell insulating film 130 may be a single film. For example, the first cell insulating film 131 may include silicon oxide, while the second cell insulating film 132 may include silicon nitride. However, embodiments of the present disclosure are not limited thereto. In another example, unlike what is shown, the cell insulating film 130 may include three or more insulating films. When the cell insulating film 130 includes a third cell insulating film, the third cell insulating film may be a silicon oxide film.

In the cross-sectional view of FIG. 5, the upper surface of the substrate 100US may be defined at a boundary between the cell insulating film 130 and the substrate 100.

A cell line spacer 150 may be disposed on a sidewall of each of the cell conductive line 140 and the cell line capping film 144. The cell line spacer 150 may be formed on the substrate 100 and the cell element isolation film 105 in an area around an area in which the cell conductive line 140 is disposed on the bit-line contact 146. The cell line spacer 150 may be disposed on a sidewall of each of the cell conductive line 140, the cell line capping film 144, and the bit-line contact 146.

In an area around an area in which the cell conductive line 140 is formed and the bit-line contact 146 is absent, the cell line spacer 150 may be disposed on the cell insulating film 130. The cell line spacer 150 may be disposed on a sidewall of each of the cell conductive line 140, and the cell line capping film 144.

The cell line spacer 150 may be disposed on a major sidewall extending in the second direction DR2 in an elongate manner among the sidewalls of the bit-line structure 140ST.

The cell line spacer 150 is illustrated as a stack of multiple films including first to fourth cell line spacers 151, 152, 153, and 154. However, the cell line spacer 150 may be a single film. For example, each of the first to fourth cell line spacers 151, 152, 153, and 154 may include one of a silicon oxide film, a silicon nitride film, a silicon oxynitride film (SiON), a silicon oxycarbonitride film (SiOCN), air, or a combination thereof. However, embodiments of the present disclosure are not limited thereto. For example, the second cell line spacer 152 may not be disposed on the cell conductive film 130, but may be disposed on a sidewall of the bit-line contact 146.

A fence pattern 170 may be disposed on the substrate 100 and the cell element isolation film 105. The fence pattern 170 may be formed to overlap the cell gate structure 110 formed in the substrate 100 and the cell element isolation film 105. The fence pattern 170 may be disposed between the bit-line structures 140ST extending in the second direction DR2. The fence pattern 170 may include, for example, one of silicon oxide, silicon nitride, silicon oxynitride, or combinations thereof.

The storage contacts 120 may be disposed between the cell conductive lines 140 adjacent to each other in the first direction DR1. The storage contacts 120 may be respectively disposed on both opposing sides of the bit line structure 140ST. The storage contacts 120 may be disposed between the fence patterns 170 adjacent to each other in the second direction DR2. The storage contact 120 may overlap a portion of each of the substrate 100 and the cell element isolation film 105 disposed between adjacent cell conductive lines 140.

The storage contact 120 may be connected to the storage connection area 103b of the cell active area ACT. In this regard, the storage contact 120 may correspond to the buried contact BC of FIG. 2.

The storage contact 120 may include, for example, at least one of an impurity-doped semiconductor material, a conductive metal nitride, a conductive metal carbonitride, a conductive metal carbide, a metal silicide, a conductive metal oxynitride, a conductive metal oxide, or a metal. In the semiconductor memory device according to some embodiments, the storage contact 120 may include an impurity-doped semiconductor material.

The storage pads 160 may be disposed on the storage contacts 120. The storage pad 160 may be electrically connected to the storage contact 120. In this regard, the storage pad 160 may correspond to the landing pad LP of FIG. 2.

The storage pad 160 may overlap a portion of an upper surface of the bit line structure 140ST. For example, the storage pad 160 may overlap an upper surface of the cell line capping film 144US in the fourth direction DR4. The fourth direction DR4 may be the thickness direction of the substrate 100. Each of the first direction DR1, the second direction DR2, and the third direction DR3 may be perpendicular to the fourth direction DR4.

The storage pad 160 may include a lower storage pad 160B and an upper storage pad 160U. The lower storage pad 160B and the upper storage pad 160U may be sequentially stacked on the corresponding storage contact 120 in the fourth direction DR4.

The lower storage pad 160B may be disposed on the storage contact 120. The lower storage pad 160B may be connected to the storage contact 120. For example, the lower storage pad 160B may be in contact with the storage contact 120.

The lower storage pad 160B may be disposed between bit line structures 140ST adjacent to each other in the first direction DR1 and between fence patterns 170 adjacent to each other in the second direction DR2. Based on the upper surface of the substrate 100US, the lower storage pad 160B may be disposed under the upper surface of the cell line capping film 144US. In other words, based on the upper surface of the substrate 100US, a vertical level of the uppermost position of the lower storage pad 160B may be lower than a vertical level of the upper surface of the cell line capping film 144US.

The lower storage pad 160B may include a lower pad silicide film 161 and a lower pad filling film 162. The lower pad silicide film 161 may be disposed between the storage contact 120 and the lower pad filling film 162.

The lower storage pad 160B may include a metal or a compound including a metal. The compound including the metal may include, for example, a conductive metal nitride, a conductive metal carbonitride, a conductive metal carbide, a metal silicide, a conductive metal oxynitride, or a conductive metal oxide. The lower pad silicide film 161 may include a metal silicide. The lower pad filling film 162 may include, but is not limited to, at least one of a metal or a metal nitride.

The upper storage pad 160U may be disposed on the lower storage pad 160B. The upper storage pad 160U may be in contact with the lower storage pad 160B. For example, the upper storage pad 160U may be in contact with the lower pad filling film 162.

The upper storage pad 160U may overlap the upper surface of the cell line capping film 144US in the fourth direction DR4. At least a portion of the upper storage pad 160U may be disposed on the upper surface of the cell line capping film 144US.

The upper storage pad 160U may include an upper surface 160U_US and a bottom surface 160U_BS that are opposite to each other in the fourth direction DR4. The upper storage pad 160U may include a side wall 160U_SW that connects the upper surface of the upper storage pad 160U_US and the bottom surface 160U_BS of the upper storage pad to each other.

The upper surface of the upper storage pad 160U_US may be the upper surface of the storage pad 160US. In a cross-sectional view as shown in FIG. 5, the bottom surface 160U_BS of the upper storage pad may be in contact with the lower storage pad 160B, the cell line spacer 150, and the bit line structure 140ST. The sidewall of the upper storage pad 160U_SW may be covered with a pad isolation pattern 180 to be described later.

In the semiconductor memory device according to some embodiments, the upper storage pad 160U may include a first portion 160U_P1 and a second portion 160U_P2. The first portion of the upper storage pad 160U_P1 is disposed on the second portion of the upper storage pad 160U_P2. The second portion of the upper storage pad 160U_P2 is disposed between the first portion of the upper storage pad 160U_P1 and the lower storage pad 160B.

Based on the upper surface of the cell line capping film 144US, the first portion of the upper storage pad 160U_P1 and the second portion of the upper storage pad 160U_P2 may be distinguished from each other. The first portion of the upper storage pad 160U_P1 is disposed on or above the upper surface of the cell line capping film 144US.

A width of the upper storage pad 160U disposed on top of the upper surface of the cell line capping film 144US may increase as the upper storage pad 160U is further away (i.e., with distance) from the upper surface of the cell line capping film 144US. For example, a width W21 of an upper surface of the upper storage pad 160U_US may be greater than a width W22 of the upper storage pad 160U at a vertical level (e.g., along direction DR4) corresponding to a vertical level of the upper surface of the cell line capping film 144US.

A width of the first portion of the upper storage pad 160U_P1 may increase as the first portion of the upper storage pad 160U_P1 is further away from the bit line structure 140ST. That is, the width of the first portion of the upper storage pad 160U_P1 may increase as the first portion of the upper storage pad 160U_P1 is further away from the upper surface of the cell line capping film 144US.

The upper surface of the cell line capping film 144US may include a first portion that contacts the upper storage pad 160U and a second portion that does not contact the upper storage pad 160U. For example, based on the upper surface of the substrate 100US, a vertical level of the first portion of the upper surface of the cell line capping film 144US may be lower than a vertical level of the second portion of the upper surface of the cell line capping film 144US. While the upper storage pad 160U is formed, a portion of the cell line capping film 144 may be etched, so that the vertical level of the second portion of the upper surface of the cell line capping film 144US may be lower than the vertical level of the first portion of the upper surface of the cell line capping film 144US.

The upper storage pad 160U may include a metal or a compound including a metal. For example, the upper storage pad 160U may include at least one of a metal or a metal nitride. However, embodiments of the present disclosure are not limited thereto.

The pad isolation pattern 180 may be formed on the storage pad 160 and the bit line structure 140ST. For example, the pad isolation pattern 180 may be disposed on the cell line capping film 144 and the lower storage pad 160B.

The pad isolation pattern 180 may define an area of the storage pad 160 acting as each of a plurality of isolated areas. The pad isolation pattern 180 may isolate adjacent storage pads 160 from each other. The pad isolation pattern 180 may surround the sidewall of the upper storage pad 160U_SW.

The pad isolation pattern 180 does not cover the upper surface of the storage pad 160US. The upper surface of the pad isolation pattern 180US may be coplanar with the upper surface of the storage pad 160US. However, embodiments of the present disclosure are not limited thereto.

The pad isolation pattern 180 includes an insulating material. The pad isolation pattern 180 may electrically isolate the storage pads 160 from each other. For example, the pad isolation pattern 180 may electrically isolate the upper storage pads 160U from each other. The pad isolation pattern 180 may include, for example, at least one of silicon oxide, silicon nitride, silicon oxynitride, silicon oxycarbonitride, or silicon carbonitride.

In FIG. 5 and FIG. 8, a height H31 from the lowermost position of the pad isolation pattern 180 to the upper surface of the pad isolation pattern 180US may be greater than a height H32 from the lowermost position of the upper storage pad 160U to the upper surface of the pad isolation pattern 180US.

An upper etch-stop film 292 may be disposed on the pad isolation pattern 180 and the storage pad 160. The upper etch-stop film 292 may extend along and on the upper surface of the pad isolation pattern 180US and the upper surface of the storage pad 160US.

The upper etch-stop film 292 may extend across the cell area 20 and to the peripheral area 24. The upper etch-stop film 292 may include at least one of silicon nitride, silicon carbonitride, silicon boron nitride, silicon oxynitride, and silicon oxycarbide. However, embodiments of the present disclosure are not limited thereto.

The data storage patterns 190 may be disposed on the storage pads 160. The data storage patterns 190 may be disposed on the upper surface of the cell line capping film 144US.

The data storage pattern 190 may be electrically connected to the storage pad 160. The data storage pattern 190 may be connected to the upper surface of the upper storage pad 160U_US.

A portion of the data storage pattern 190 may be disposed within the upper etch stop film 292. The data storage pattern 190 may include, for example, a data storage pattern. However, embodiments of the present disclosure are not limited thereto. The data storage pattern 190 includes a lower electrode 191, a capacitor dielectric film 192, and an upper electrode 193.

The lower electrode 191 may be disposed on the storage pad 160. The lower electrode 191 may be in contact with the upper surface of the storage pad 160US 160. The lower electrode 191 is shown as having a pillar shape. However, embodiments of the present disclosure are not limited thereto. In another example, the lower electrode 191 may have a cylindrical shape.

The capacitor dielectric film 192 is disposed on the lower electrode 191. The capacitor dielectric film 192 may be formed along a profile of the lower electrode 191. The upper electrode 193 is disposed on the capacitor dielectric film 192. The upper electrode 193 may surround an outer sidewall of the lower electrode 191.

For example, the capacitor dielectric film 192 may be disposed so as to overlap the upper electrode 193 in the fourth direction DR4. The capacitor dielectric film 192 may not extend to the peripheral area 24.

Each of the lower electrode 191 and the upper electrode 193 may include, for example, a doped semiconductor material, a conductive metal nitride such as titanium nitride, tantalum nitride, niobium nitride or tungsten nitride, etc., a metal such as ruthenium, iridium, titanium, or tantalum, etc., or a conductive metal oxide such as iridium oxide or niobium oxide, etc. However, embodiments of the present disclosure are not limited thereto.

For example, the capacitor dielectric film 192 may include at least one of a ferroelectric material, an antiferroelectric material, and a paraelectric material. For example, the capacitor dielectric film 192 may include at least one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, or a combination of a ferroelectric material, an antiferroelectric material, and a paragenetic material.

In one example, the capacitor dielectric film 192 may include a stacked film structure in which a zirconium oxide film, an aluminum oxide film, and a zirconium oxide film are sequentially stacked. In another example, the capacitor dielectric film 192 may include a dielectric film including hafnium (Hf). The suggestion regarding the material of the capacitor dielectric film 192 as described above is merely an example, and the technical idea of the present disclosure is not limited thereto.

Unlike what is described above, the data storage pattern 190 may be a variable resistance pattern that may be switched to between two resistance states under an electrical pulse applied to a memory element. For example, the data storage pattern 190 may include a phase-change material whose a crystal state changes depending on an amount of current, perovskite compounds, transition metal oxides, magnetic materials, ferromagnetic materials, or antiferromagnetic materials.

A peripheral element isolation film 26 may be disposed within the substrate 100 and in the peripheral area 24. The peripheral element isolation film 26 may define a peripheral active area int the peripheral area 24. An upper surface of the peripheral element isolation film 26 is shown as being coplanar with the upper surface of the substrate 100US. However, embodiments of the present disclosure are not limited thereto. The peripheral element isolation film 26 may include, but is not limited to, at least one of, for example, a silicon oxide film, a silicon nitride film, and a silicon oxynitride film.

The peripheral gate structure 240ST may be disposed on the substrate 100 and in peripheral area 24. The peripheral gate structure 240ST may be disposed on a peripheral active area defined by the peripheral element isolation film 26.

The peripheral gate structure 240ST may include a peripheral gate insulating film 230, a peripheral gate conductive film 240, and a peripheral capping film 244 sequentially stacked on the substrate 100. The peripheral gate structure 240ST may include a peripheral spacer 245 disposed on a sidewall of the peripheral gate conductive film 240 and a sidewall of the peripheral capping film 244.

The peripheral gate conductive film 240 may include first to third peripheral conductive films 241, 242, and 243 sequentially stacked on the peripheral gate insulating film 230. For example, an additional conductive film may not be disposed between the peripheral gate conductive film 240 and the peripheral gate insulating film 230. In another example, unlike what is shown, an additional conductive film, such as a work function conductive film, may be disposed between the peripheral gate conductive film 240 and the peripheral gate insulating film 230.

Although two peripheral gate structures 240ST are shown as being disposed between adjacent peripheral element isolation films 26, this is only for convenience of illustration and embodiments of the present disclosure are not limited thereto.

For example, the peripheral gate conductive film 240 may have the same stacked structure as that of the cell conductive line 140. However, embodiments of the present disclosure are not limited thereto. Each of the first to third peripheral conductive films 241, 242, and 243 may include, for example, at least one of a semiconductor material doped with an impurity, a conductive metal nitride, a conductive metal carbonitride, a conductive metal carbide, a metal silicide, a conductive metal oxynitride, a conductive metal oxide, a two-dimensional material, or a metal.

The peripheral gate insulating film 230 may include, for example, silicon oxide, silicon nitride, silicon oxynitride, or a high dielectric constant material having a higher dielectric constant than that of silicon oxide.

For example, the peripheral spacer 245 may include at least one of silicon nitride, silicon oxynitride, silicon oxide, silicon carbonitride, silicon oxycarbonitride, and combinations thereof. Although the peripheral spacer 245 is shown as being formed as a single film, this is only for convenience of illustration and embodiments of the present disclosure are not limited thereto. In another example, the peripheral spacer 245 may be a stack of multi-films. For example, the peripheral capping film 244 may include at least one of silicon nitride, silicon oxynitride, and silicon oxide.

A lower etch stop film 250 may be disposed on the substrate 100. The lower etch stop film 250 may be formed along a profile of the peripheral gate structure 240ST. For example, the lower etch stop film 250 may include at least one of silicon nitride, silicon oxynitride, silicon carbonitride, and silicon oxycarbonitride.

A first peripheral interlayer insulating film 290 may be disposed on the lower etch stop film 250. The first peripheral interlayer insulating film 290 may be disposed around the peripheral gate structure 240ST. For example, the first peripheral interlayer insulating film 290 may include a silicon oxide-based insulating material. The first peripheral interlayer insulating film 290 may include, but is not limited to, silicon oxide.

Based on the upper surface of the substrate 100US, a vertical level of the upper surface of the first peripheral interlayer insulating film 290US may be lower than a vertical level of the upper surface of the peripheral capping film 244US. For example, a height H1 from the upper surface of the substrate 100US to an upper surface of the first peripheral interlayer insulating film 290US may be smaller than a height H21 from the upper surface of the substrate 100US to an upper surface of the peripheral capping film 244US.

The height H1 from the upper surface of the substrate 100US to the upper surface of the first peripheral interlayer insulating film 290US may be measured at a position near a center between adjacent peripheral gate structures 240ST. The height H21 from the upper surface of the substrate 100US to the upper surface of the peripheral capping film 244US may be measured at a position near a center of a width of the peripheral capping film 244.

The height H1 from the upper surface of the substrate 100US to the upper surface of the first peripheral interlayer insulating film 290US may be smaller than a height H22 from the upper surface of the substrate 100US to a top level of the peripheral spacer 245.

For example, the height H21 from the upper surface of the substrate 100US to the upper surface of the peripheral capping film 244US may be equal to the height H22 from the upper surface of the substrate 100US to the top level of the peripheral spacer 245.

Unlike what is shown, in another example, a vertical level of the upper surface of the peripheral spacer 245 may be lower than a vertical level of the upper surface of the peripheral capping film 244US due to an etching process during the manufacturing process. In this case, the height H21 from the upper surface of the substrate 100US to the upper surface of the peripheral capping film 244US may be greater than or equal to the height H22 from the upper surface of the substrate 100US to the top level of the peripheral spacer 245.

An inserted interlayer insulating film 291 is disposed on the peripheral gate structure 240ST and the first peripheral interlayer insulating film 290. The inserted interlayer insulating film 291 may cover the peripheral gate structure 240ST and the first peripheral interlayer insulating film 290. The inserted interlayer insulating film 291 may cover a portion of the lower etch stop film 250 that protrudes upwardly beyond the upper surface of the first peripheral interlayer insulating film 290US.

The upper surface of the first peripheral interlayer insulating film 290US is shown as being flat. However, embodiments of the present disclosure are not limited thereto. The upper surface of the first peripheral interlayer insulating film 290US may be a curved surface convex toward substrate 100.

The inserted interlayer insulating film 291 may include a material different from that of the first peripheral interlayer insulating film 290. The inserted interlayer insulating film 291 may include, for example, a silicon nitride-based insulating material. For example, the inserted interlayer insulating film 291 may include silicon nitride.

A portion of the inserted interlayer insulating film 291 extends downwardly into a space between adjacent peripheral gate structures 240ST. In other words, based on the upper surface of the substrate 100US, a vertical level of the lower surface of the inserted interlayer insulating film 291 may be lower than a vertical level of the upper surface of the peripheral capping film 244US.

Thus, the inserted interlayer insulating film 291 may protect the first peripheral interlayer insulating film 290 in an etching process included in a process of manufacturing the data storage pattern 190. In the etching process included in the process of manufacturing the data storage pattern 190, the inserted interlayer insulating film 291 may prevent defects caused by etching the first peripheral interlayer insulating film 290.

Peripheral contact plugs 260 may be respectively disposed on both opposing sides of the peripheral gate structure 240ST. The peripheral contact plug 260 may extend through the inserted interlayer insulating film 291 and the first peripheral interlayer insulating film 290 to a portion of the substrate 100 in the peripheral area 24.

The peripheral contact plug 260 may include a peripheral plug barrier film 261 and a peripheral plug filling film 262. The peripheral plug filling film 262 may be disposed on the peripheral plug barrier film 261.

The peripheral wiring lines 265 may be disposed on the inserted interlayer insulating film 291. The peripheral wiring line 265 may be disposed on the peripheral gate structure 240ST. The peripheral wiring line 265 may be connected to the peripheral contact plug 260. In the cross-sectional view, when the peripheral wiring line 265 is connected to the peripheral contact plug 260, the peripheral wiring line 265 may be a portion disposed on the upper surface of the inserted interlayer insulating film 291US. The peripheral wiring line 265 may be disposed on the upper surface of the inserted interlayer insulating film 291US.

The peripheral wiring line 265 may include a peripheral wiring barrier film 266 and a peripheral wiring extension line 267. The peripheral wiring extension line 267 may be disposed on the peripheral wiring barrier film 266.

The peripheral wiring line 265 may include an upper surface 265US and a bottom surface 265BS opposite to each other in the fourth direction DR4. The bottom surface of the peripheral wiring line 265BS may face the inserted interlayer insulating film 291. The peripheral wiring line 265 may include a side wall 265SW connecting the bottom surface of the peripheral wiring line 265BS and the upper surface of the peripheral wiring line 265US to each other.

The peripheral wiring extension line 267 may include the upper surface of the peripheral wiring line 265US. The sidewall of the peripheral wiring line 265SW may be defined by the peripheral wiring barrier film 266 and the peripheral wiring extension line 267.

In a semiconductor memory device according to some embodiments, the peripheral wiring extension line 267 may be directly connected to the peripheral plug filling film 262. The peripheral wiring barrier film 266 may be directly connected to the peripheral plug barrier film 261. The peripheral contact plug 260 and the peripheral wiring line 265 may be formed in the same manufacturing process.

The peripheral wiring barrier film 266 may include the same material as that of the peripheral plug barrier film 261. The peripheral wiring barrier film 266 may include, for example, one of a metal silicide compound, a conductive metal nitride, a conductive metal carbide, a conductive metal oxide, a conductive metal oxynitride, or a conductive metal carbonitride.

The peripheral wiring extension line 267 may include the same material as that of the peripheral plug filling film 262. The peripheral wiring extension line 267 may include a metal. For example, the peripheral wiring extension line 267 may be made of a metal.

Unlike the illustrated example, in another example, the peripheral contact plug 260 may include the peripheral plug barrier film 261 and may be free of the peripheral plug filling film 262. In still another example, the peripheral contact plug 260 may include the peripheral plug filling film 262 made of metal and may be free of the peripheral plug barrier film 261. The peripheral wiring line 265 may include the peripheral wiring extension line 267 made of metal and may be free of the peripheral wiring barrier film 266.

For example, a width W12 of the bottom surface of the peripheral wiring line 265BS may be greater than or equal to a width W11 of the upper surface of the peripheral wiring line 265US.

The peripheral wiring isolation pattern 280 may isolate adjacent peripheral wiring lines 265 from each other. The peripheral wiring line 265 includes a first peripheral wiring line 265_1 and a second peripheral wiring line 265_2 adjacent to each other, and the peripheral wiring isolation pattern 280 isolates the first peripheral wiring line 265_1 and the second peripheral wiring line 265_2 from each other.

The peripheral wiring isolation pattern 280 may cover the side wall of the peripheral wiring line 265SW. The upper surface of the peripheral wiring isolation pattern 280US may be coplanar with the upper surface of the peripheral wiring line 265US. However, embodiments of the present disclosure are not limited thereto.

The peripheral wiring isolation pattern 280 includes an insulating material. The peripheral wiring isolation pattern 280 may electrically isolate adjacent peripheral wiring lines 265 from each other. For example, the peripheral wiring isolation pattern 280 may include at least one of silicon oxide, silicon nitride, silicon oxynitride, silicon oxycarbonitride, and silicon carbonitride.

The upper etch-stop film 292 may be disposed on the peripheral wiring isolation pattern 280 and the peripheral wiring line 265. For example, the upper etch-stop film 292 may extend along and on the upper surface of the peripheral wiring line 265US and the upper surface of the peripheral wiring isolation pattern 280US.

A second peripheral interlayer insulating film 293 may be disposed on the upper etch-stop film 292. Although not shown, the second peripheral interlayer insulating film 293 may cover a sidewall of the upper electrode 193. The second peripheral interlayer insulating film 293 may include an insulating material.

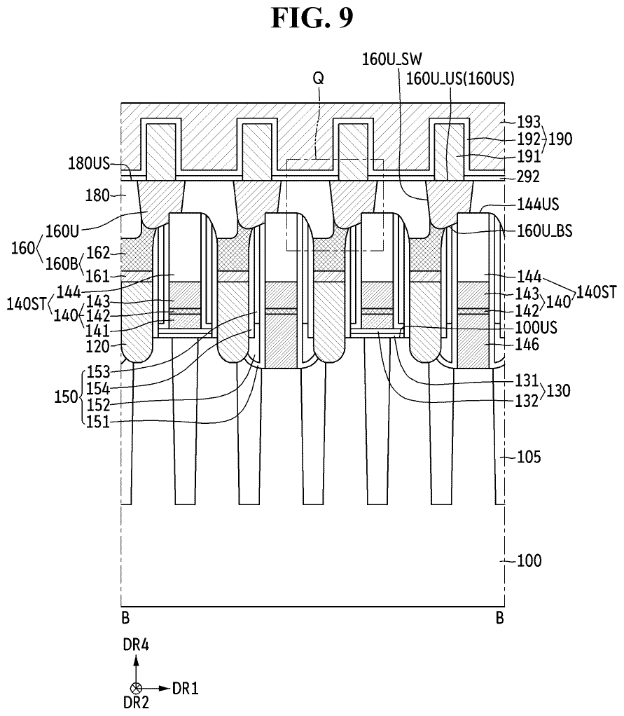

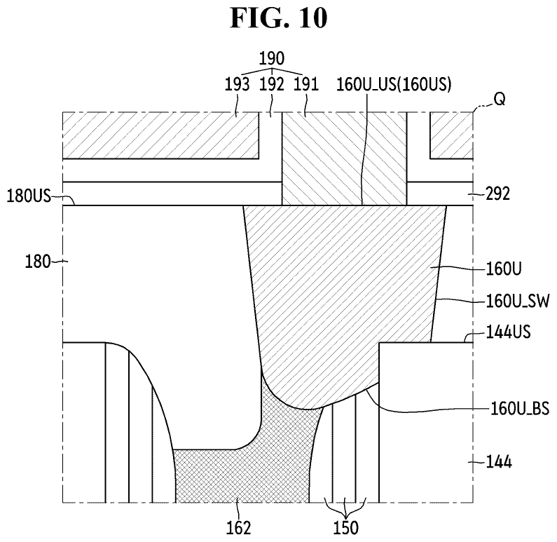

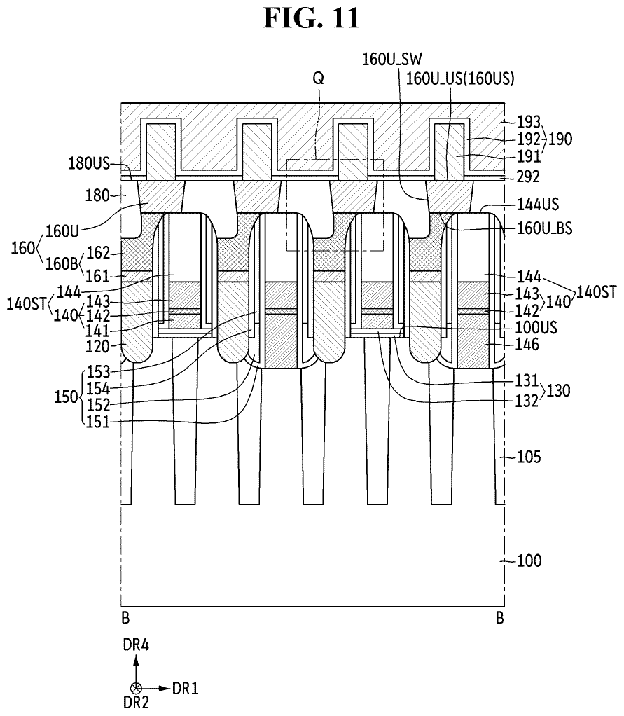

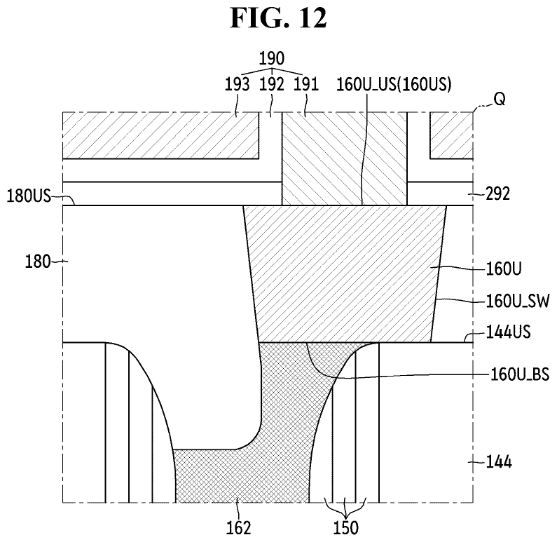

FIG. 9 and FIG. 10 are diagrams for illustrating a semiconductor memory device according to some embodiments. FIG. 11 and FIG. 12 are diagrams for illustrating a semiconductor memory device according to some embodiments. For convenience of description, following descriptions are mainly based on differences thereof from the descriptions as set forth above with reference to FIGS. 1 to 8.

For reference, FIG. 10 and FIG. 12 are diagrams that enlarge portions Q of FIG. 9 and FIG. 11, respectively.

Referring to FIG. 9 and FIG. 10, in the semiconductor memory device according to some embodiments, in a cross-sectional view, the upper surface of the cell line capping film 144US may be flat.

Based on the upper surface of the substrate 100US, a vertical level of a portion of the upper surface of the cell line capping film 144US that contacts the upper storage pad 160U may be equal to a vertical level of a portion of the upper surface of the cell line capping film 144US that does not contact the upper storage pad 160U.

Referring to FIG. 11 and FIG. 12, in the semiconductor memory device according to some embodiments, an entirety of the upper storage pad 160U may be disposed on the upper surface of the cell line capping film 144US and the lower pad filling film 162.

Based on the upper surface of the substrate 100US, a vertical level of an entirety of the upper storage pad 160U may be higher than that of the upper surface of the cell line capping film 144US. For example, a boundary surface of the lower pad filling film 162 in contact with the upper storage pad 160U may be coplanar with the upper surface of the cell line capping film 144US.

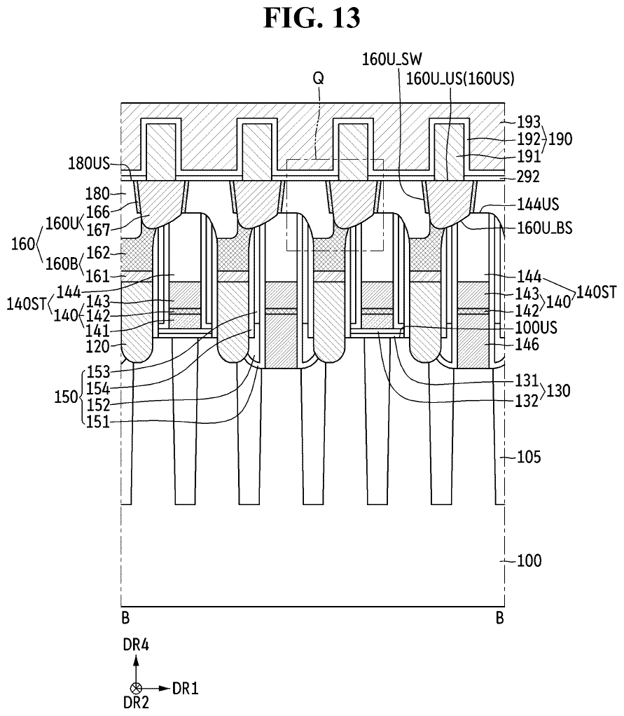

FIGS. 13 to 15 are diagrams for illustrating a semiconductor memory device according to some embodiments. For convenience of description, following descriptions are mainly based on differences thereof from the descriptions as set forth above using FIG. 1 to FIG. 8.

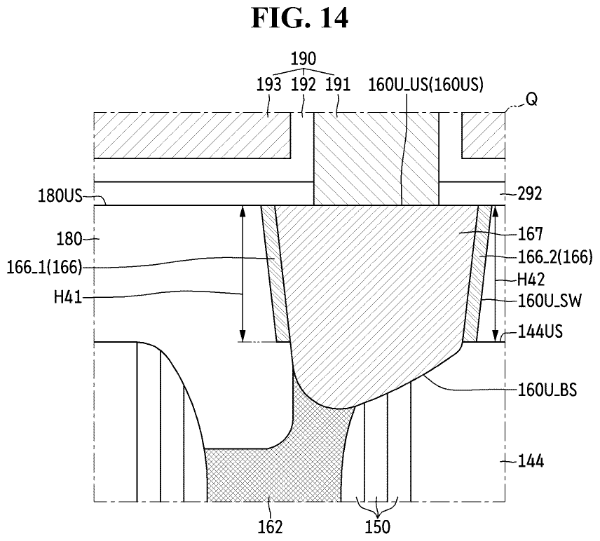

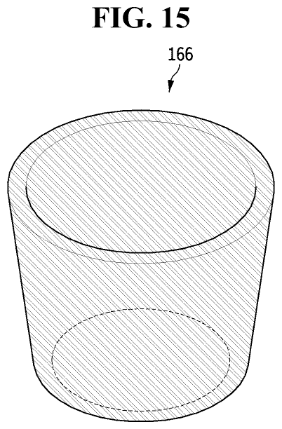

For reference, FIG. 14 is a diagram that enlarges a portion Q of FIG. 13. FIG. 15 is a diagram of an example of a three-dimensional shape of the upper pad silicide film of FIG. 13.

Referring to FIGS. 13 to 15, in a semiconductor memory device according to some embodiments, the upper storage pad 160U may include an upper pad silicide film 166 and an upper pad filling film 167.

The upper pad silicide film 166 may include a sidewall of the upper storage pad 160U_SW. At least a portion of the sidewall of the upper storage pad 160U_SW may be defined by the upper pad silicide film 166.

The upper pad silicide film 166 may be disposed along a boundary surface between the upper pad filling film 167 and the pad isolation pattern 180. In FIG. 15, the upper pad silicide film 166 may have a cylindrical shape.

The upper pad silicide film 166 and the upper pad filling film 167 may include the upper surface of the upper storage pad 160U_US. In a plan view, the upper surface of the upper storage pad 160U_US defined by the upper pad silicide film 166 may surround a perimeter of the upper surface of the upper storage pad 160U_US defined by the upper pad filling film 167.

The upper pad filling film 167 may be in contact with the lower pad filling film 162. The upper pad silicide film 166 may not be disposed between the upper pad filling film 167 and the lower pad filling film 162. More specifically, the upper pad silicide film 166 does not extend along a boundary surface between the upper pad filling film 167 and the lower pad filling film 162.

The upper pad silicide film 166 is not directly connected to the lower pad silicide film 161. The lower pad filling film 162 is positioned between the upper pad silicide film 166 and the lower pad silicide film 161. The upper pad silicide film 166 and the lower pad silicide film 161 may be isolated from each other via the lower pad filling film 162.

In a cross-sectional view of FIG. 13 and FIG. 14, the upper pad silicide film 166 may include a first upper pad silicide film 166_1 and a second upper pad silicide film 166_2 spaced from each other while the upper pad filling film 167 is interposed therebetween. The first upper pad silicide film 166_1 and the second upper pad silicide film 166_2 may be spaced apart from each other in the first direction DR1. In the semiconductor memory device according to some embodiments, a height H41 of the first upper pad silicide film 166_1 in the fourth direction DR4 may be equal to a height H42 of the second upper pad silicide film 166_2 in the fourth direction DR4.

The upper pad silicide film 166 may include a metal silicide. The upper pad filling film 167 may include at least one of a metal or a metal nitride. However, embodiments of the present disclosure are not limited thereto.

The upper pad silicide film 166 may include a silicide of a metal included in the upper pad filling film 167. For example, when the upper pad filling film 167 includes tungsten (W), the upper pad silicide film 166 may include tungsten silicide.

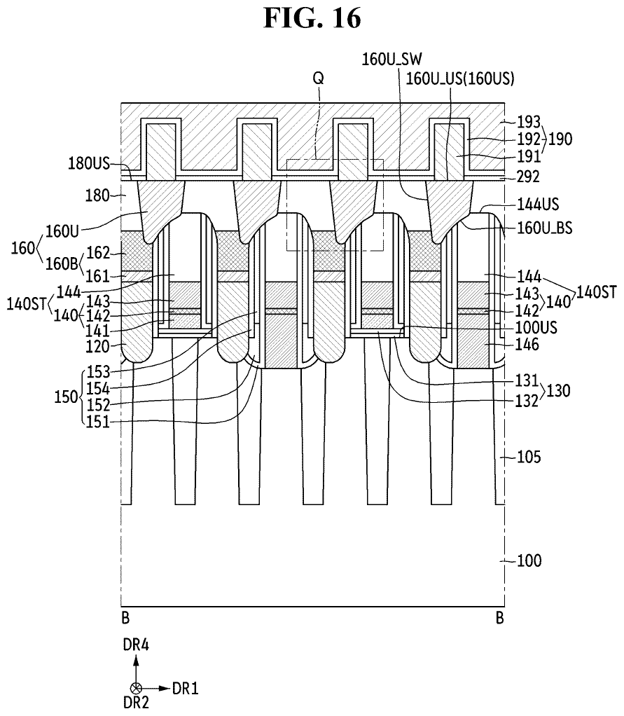

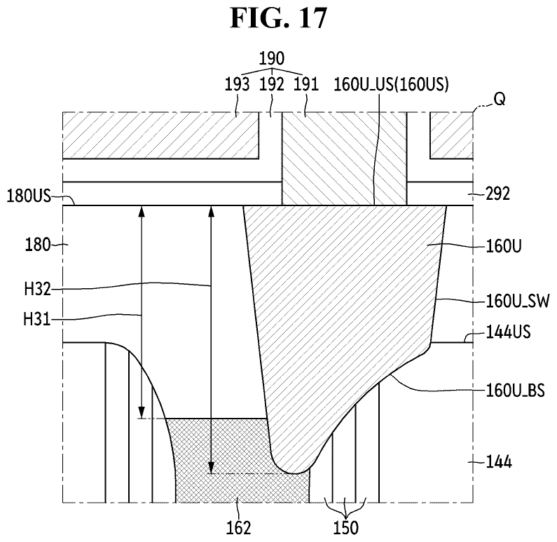

FIG. 16 and FIG. 17 are diagrams for illustrating a semiconductor memory device according to some embodiments. For convenience of description, following descriptions are mainly based on differences thereof from the descriptions as set forth above using FIG. 1 to FIG. 8.

Referring to FIG. 16 and FIG. 17, in the semiconductor memory device according to some embodiments, a height H31 from the lowermost position of the pad isolation pattern 180 to the upper surface of the pad isolation pattern 180US may be smaller than a height H32 from the lowermost position of the upper storage pad 160U to the upper surface of the pad isolation pattern 180US.

Based on the upper surface of the substrate 100US, a vertical level of the lowermost position of the pad isolation pattern 180 may be higher than a vertical level of the lowermost position of the upper storage pad 160U.

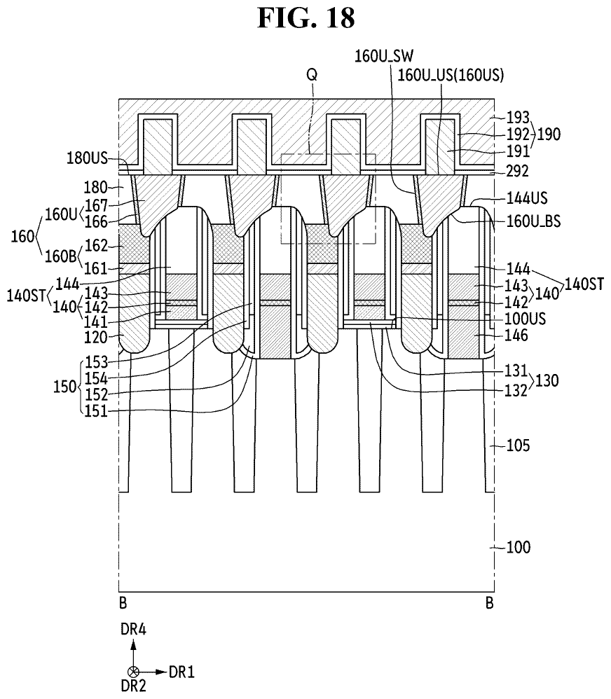

FIGS. 18 to 20 are diagrams for illustrating a semiconductor memory device according to some embodiments. For convenience of description, following descriptions are mainly based on differences thereof from the descriptions as set forth above with reference to FIGS. 13 to 17.

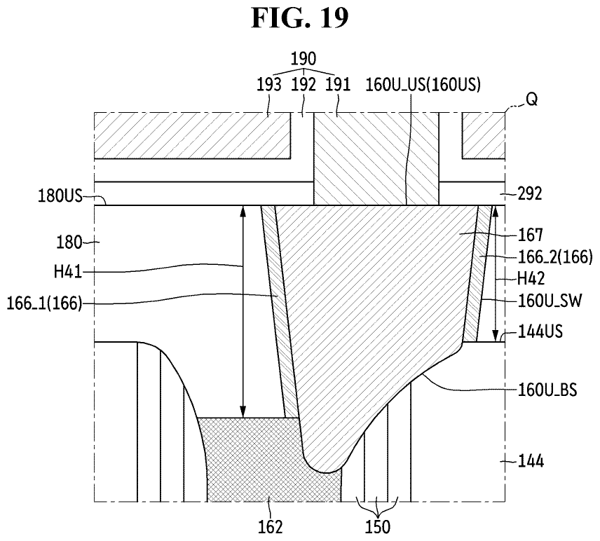

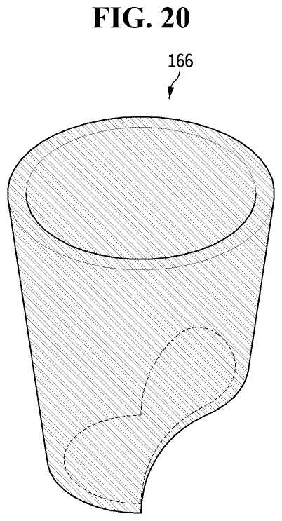

For reference, FIG. 19 is a diagram that enlarges a Portion Q of FIG. 18. FIG. 20 is a diagram of an example of a three-dimensional shape of the upper pad silicide film of FIG. 18.

Referring to FIGS. 18 to 20, in the semiconductor memory devices according to some embodiments, the sidewall of the upper storage pad 160U_SW may be defined by the upper pad silicide film 166.

For example, the upper pad filling film 167 may not be in contact with the pad isolation pattern 180.

In FIG. 18 and FIG. 20, the upper pad silicide film 166 may have a cylinder shape whose a height decreases as the upper pad silicide film 166 is further away from the lower storage pad 160B in the first direction DR1.

In a cross-sectional view of FIG. 18 and FIG. 19, the upper pad silicide film 166 may include a first upper pad silicide film 166_1 and a second upper pad silicide film 166_2 spaced apart from each other in the first direction DR1. The first upper pad silicide film 166_1 may be in contact with the lower storage pad 160B. For example, the first upper pad silicide film 166_1 may be in contact with the lower pad filling film 162. The second upper pad silicide film 166_2 may be in contact with the bit line structure 140ST. For example, the second upper pad silicide film 166_2 may be in contact with the cell line capping film 144.

For example, a height H41 of the first upper pad silicide film 166_1 in the fourth direction DR4 is greater than a height H42 of the second upper pad silicide film 166_2 in the fourth direction DR4.

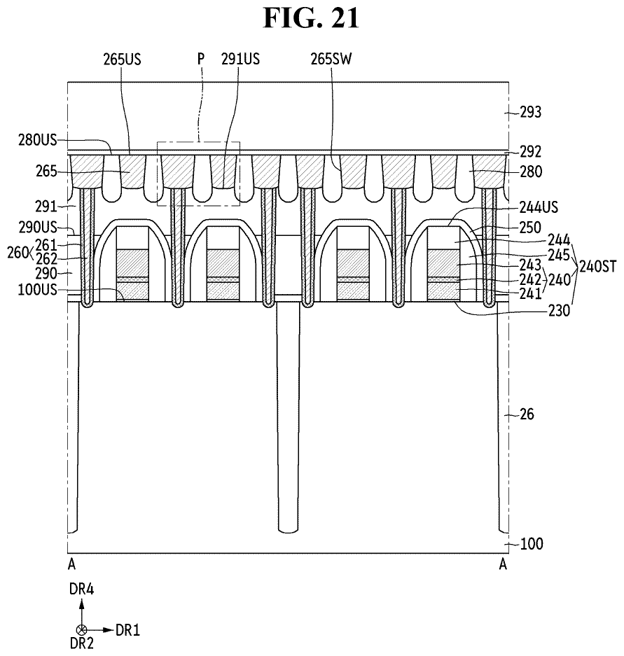

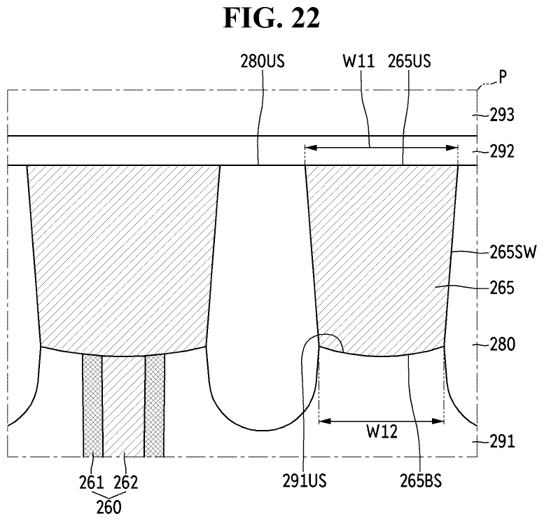

FIG. 21 and FIG. 22 are diagrams for illustrating a semiconductor memory device according to some embodiments. For convenience of description, following descriptions are mainly based on differences thereof from the descriptions as set forth above with reference to FIGS. 1 to 8.

For reference, FIG. 22 is a diagram that enlarges a portion P of FIG. 21.

Referring to FIG. 21 and FIG. 22, in the semiconductor memory device according to some embodiments, a width of the peripheral wiring line 265 may increase as the peripheral wiring line 265 is further away from the peripheral gate conductive film 240.

The width W12 of the bottom surface of the peripheral wiring line 265BS is smaller than the width W11 of the upper surface of the peripheral wiring line 265US.

In a cross-sectional view, a width of the peripheral wiring isolation pattern 280 disposed between adjacent peripheral wiring lines 265 may increase and then decrease as the peripheral wiring isolation pattern 280 is further away from the peripheral gate conductive film 240.

The peripheral wiring line 265 may include the same conductive material as that of the upper storage pad 160U in FIG. 5.

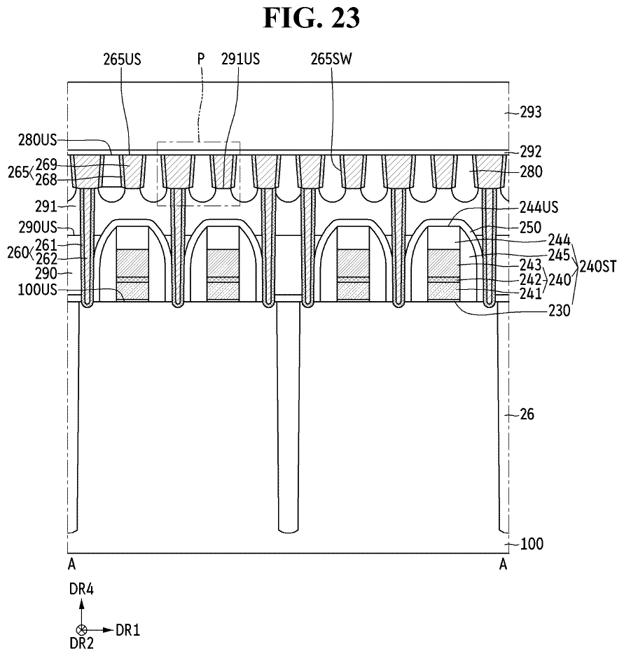

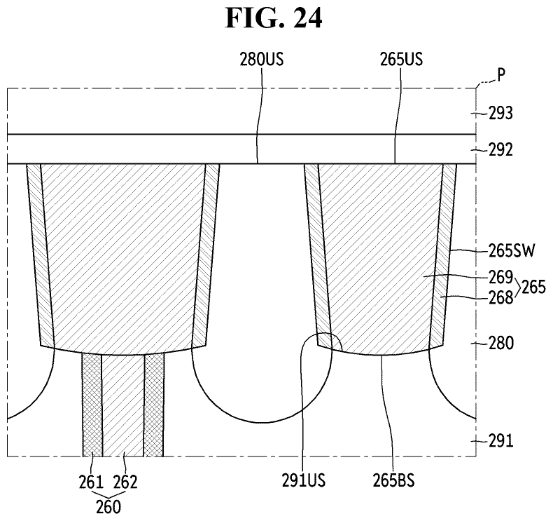

FIG. 23 and FIG. 24 are diagrams for illustrating a semiconductor memory device according to some embodiments. For convenience of description, following descriptions are mainly based on differences thereof from the descriptions as set forth above using FIG. 21 and FIG. 22. For reference, FIG. 24 is an enlarged drawing of a portion P of FIG. 23.

Referring to FIG. 23 and FIG. 24, in the semiconductor memory device according to some embodiments, the peripheral wiring line 265 may include a peripheral wiring silicide film 268 and a peripheral wiring filling film 269.

The peripheral wiring silicide film 268 may include a sidewall of the peripheral wiring line 265SW. The sidewall of the peripheral wiring line 265SW may be defined by the peripheral wiring silicide film 268.

The peripheral wiring silicide film 268 may be disposed along a boundary surface between the peripheral wiring filling film 269 and the peripheral wiring isolation pattern 280.

The peripheral wiring silicide film 268 and the peripheral wiring filling film 269 may include an upper surface of the peripheral wiring line 265US. The peripheral wiring silicide film 268 and the peripheral wiring filling film 269 may include the bottom surface of the peripheral wiring line 265BS.

The peripheral wiring filling film 269 may be in contact with the peripheral contact plug 260. The peripheral wiring filling film 269 may be in contact with the inserted interlayer insulating film 291. The peripheral wiring silicide film 268 does not extend along a boundary surface between the peripheral contact plug 260 and the peripheral wiring filling film 269. The peripheral wiring silicide film 268 does not extend along a boundary surface between the inserted interlayer insulating film 291 and the peripheral wiring filling film 269.

The peripheral wiring silicide film 268 may include a metal silicide. The peripheral wiring silicide film 268 may include a silicide of a metal included in the peripheral wiring filling film 269. The peripheral wiring filling film 269 may include the same conductive material as that of the upper pad filling film 167 of FIG. 13 or FIG. 18.

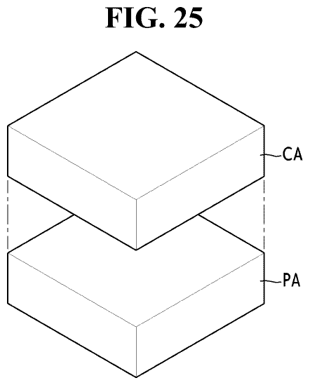

FIG. 25 is a diagram for illustrating a semiconductor memory device according to some embodiments.

Referring to FIG. 25, the semiconductor memory device according to some embodiments may have a COP (Cell on Peri) structure in which the cell array area CA is disposed on the peripheral structure area PA.

The peripheral structure area PA may correspond to the peripheral area 24 of FIG. 1 and FIG. 4. The cell array area CA may correspond to the cell area 20 of FIG. 1 to FIG. 3.

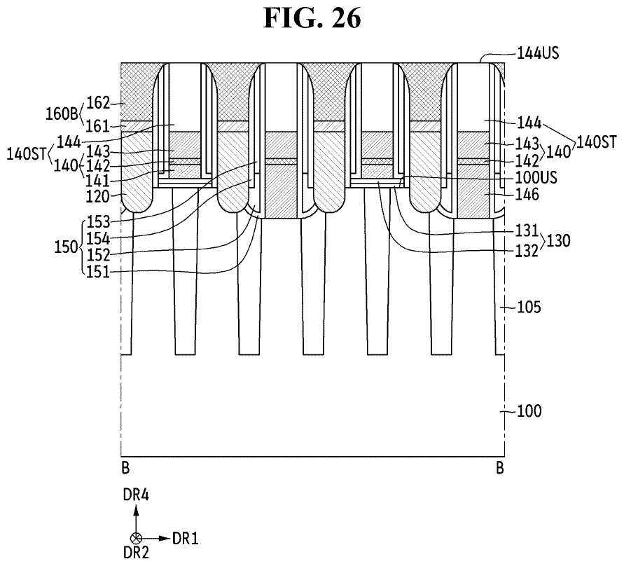

FIGS. 26 to 31 are diagrams of intermediate structures corresponding to intermediate steps of a method for manufacturing a semiconductor memory device according to some embodiments. In the description of the method for manufacturing the device, contents duplicate with the contents as described above using FIG. 1 to FIG. 8 is briefly described or the descriptions thereof are omitted.

Referring to FIG. 26, the bit line structure 140ST may be formed on the substrate 100.

The bit line structure 140ST may include the cell conductive line 140 and the cell line capping film 144 stacked in the fourth direction DR4.

The cell line spacer 150 may be formed on the side wall of the bit line structure 140ST. After forming the cell line spacer 150, the storage contact 120 may be formed between bit line structures 140ST adjacent to each other in the first direction DR1.

The lower storage pad 160B may be formed on the storage contact 120. For example, the upper surface of the lower storage pad 160B may be coplanar with the upper surface of the cell line capping film 144US.

After the lower pad silicide film 161 is formed on the storage contact 120, the lower pad filling film 162 may be formed.

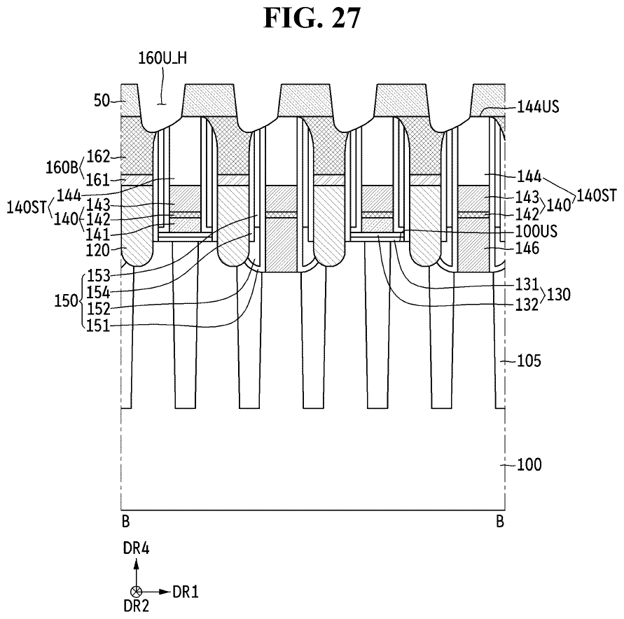

Referring to FIG. 27, a pad mask pattern 50 may be formed on the lower storage pad 160B and the bit line structure 140ST.

The pad mask pattern 50 may include a storage pad hole 160U_H that exposes the lower storage pad 160B. The storage pad hole 160U_H may expose the lower pad filling film 162.

More specifically, a polysilicon film may be formed on the lower storage pad 160B and the bit line structure 140ST. The storage pad hole 160U_H that exposes the lower storage pad 160B may be formed in the polysilicon film. Thus, the pad mask pattern 50 may be formed. A width of the storage pad hole 160U_H may increase as the storage pad hole 160U_H is further away from the lower storage pad 160B.

While the storage pad hole 160U_H is formed, a portion of the cell line capping film 144 and a portion of the lower pad filling film 162 may be etched. However, the present disclosure is not limited thereto.

The pad mask pattern 50 may include, for example, polysilicon. The polysilicon may have a high etching selectivity with respect to each of the material included in the cell line capping film 144 and the material included in the lower pad filling film 162. Due to this high etching selectivity, an etched amount of each of the cell line capping film 144 and the lower pad filling film 162 may be reduced while the storage pad hole 160U_H is formed. That is, the lowermost position of the storage pad hole 160U_H may be spaced apart from the cell conductive line 140 by a sufficient distance, for example, a margin sufficient to reduce the likelihood of an electrical short between the cell conductive line 140 and the storage pad 160U. Furthermore, the storage pad hole 160U_H may be spaced apart from another lower storage pad 160B adjacent thereto by a sufficient distance.

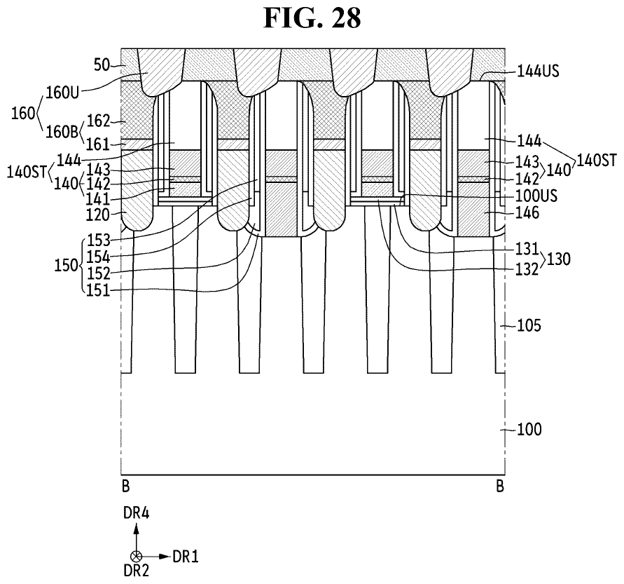

Referring to FIG. 27 and FIG. 28, the upper storage pad 160U may be formed on the lower storage pad 160B.

The upper storage pad 160U may be formed within the storage pad hole 160U_H. The upper storage pad 160U may fill the storage pad hole 160U_H. Thus, the storage pad 160 including the lower storage pad 160B and the upper storage pad 160U may be formed.

The upper storage pad 160U may be formed, for example, using a chemical vapor deposition (CVD) scheme. However, embodiments of the present disclosure are not limited thereto. Although not shown, while the upper storage pad 160U is formed, the upper pad silicide film (166 in FIG. 13) may be formed on a sidewall of the storage pad hole 160U_H. The upper pad silicide film 166 may be formed by converting a portion of polysilicon exposed through the storage pad hole 160U_H into silicide.

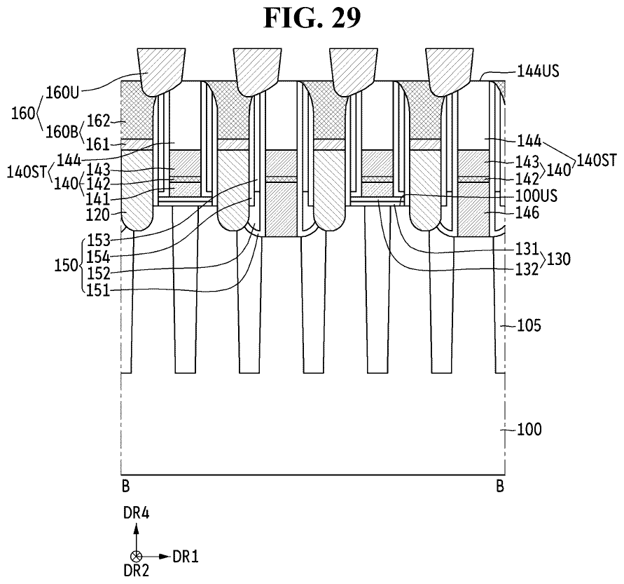

Referring to FIG. 28 and FIG. 29, the pad mask pattern 50 may be removed.

The pad mask pattern 50 may be removed so that at least a portion of the upper storage pad 160U may protrude upwardly beyond the upper surface of the cell line capping film 144US.

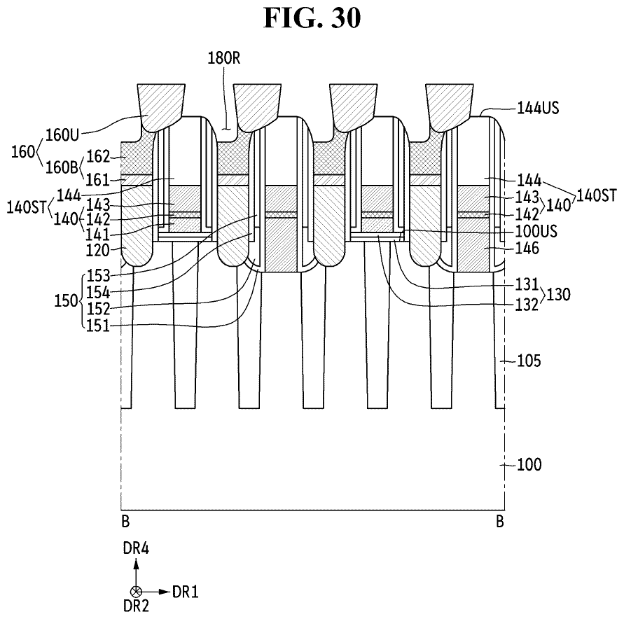

Referring to FIG. 29 and FIG. 30, another portion of the lower storage pad 160B may be removed using the upper storage pad 160U as a mask.

Thus, a pad isolation recess 180R may be formed around the upper storage pad 160U.

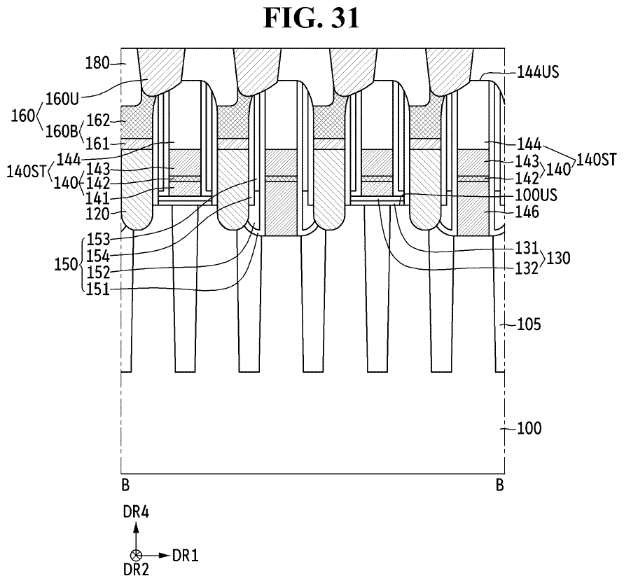

Referring to FIG. 30 and FIG. 31, the pad isolation pattern 180 may be formed on the lower storage pad 160B and the bit line structure 140ST.

The pad isolation pattern 180 may fill the pad isolation recess 180R. The pad isolation pattern 180 may be formed using a deposition process. The pad isolation pattern 180 may cover the sidewall of the upper storage pad 160U. The pad isolation pattern 180 may be formed around the upper storage pad 160U.

Although not shown, an air gap or a seam pattern may be formed within the pad isolation pattern 180 between adjacent upper storage pads 160U.

Next, referring to FIG. 5, the data storage pattern 190 may be formed on the storage pad 160.

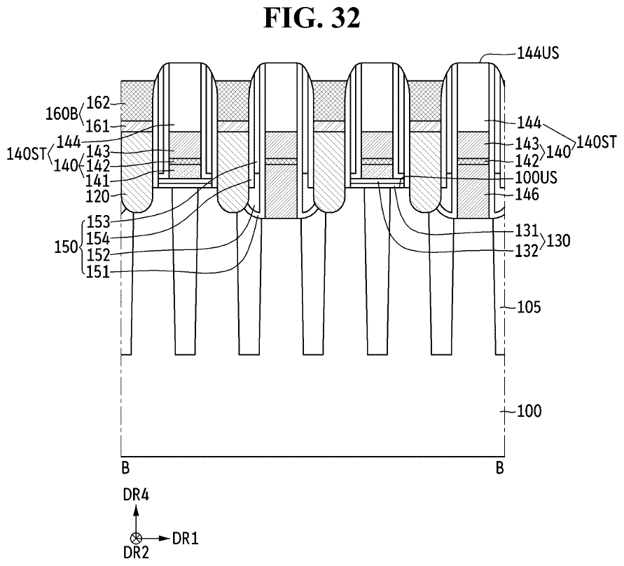

FIGS. 32 to 36 are diagrams of intermediate structures corresponding to intermediate steps for of a method for manufacturing a semiconductor memory device according to some embodiments. FIG. 32 may be a manufacturing process performed after FIG. 26.

Contents duplicate with the descriptions as set forth using FIGS. 26 to 31 regarding the descriptions of the manufacturing method is briefly described or the descriptions thereof are omitted.

Referring to FIG. 32, a portion of the lower storage pad 160B may be etched so that a vertical level of the upper surface of the lower storage pad 160B may be lowered than a vertical level of the upper surface of the cell line capping film 144US.

For example, a portion of the lower pad filling film 162 may be removed so that the vertical level of the upper surface of the lower storage pad 160B may be lowered.

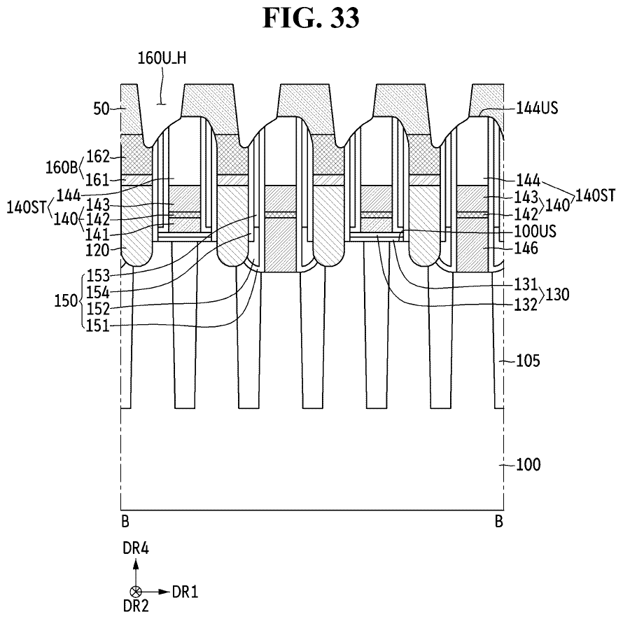

Referring to FIG. 33, a pad mask pattern 50 may be formed on the lower storage pad 160B and the bit line structure 140ST.

The pad mask pattern 50 may be formed on the lower storage pad 160B whose the upper surface has the lowered vertical level.

The pad mask pattern 50 may include a storage pad hole 160U_H that exposes the lower storage pad 160B. A portion of the storage pad hole 160U_H may extend into or may be recessed into the lower pad filling film 162. While the storage pad hole 160U_H is formed, another portion of the lower pad filling film 162 may be removed. However, embodiments of the present disclosure are not limited thereto.

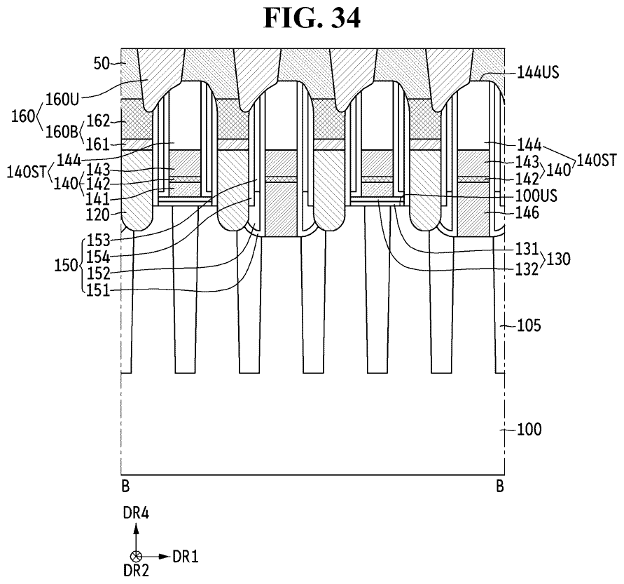

Referring to FIG. 33 and FIG. 34, the upper storage pad 160U may be formed on the lower storage pad 160B.

Thus, the storage pad 160 may be formed.

Although not shown, while the upper storage pad 160U is formed, the upper pad silicide film (166 of FIG. 18) may be formed on a sidewall of the storage pad hole 160U_H.

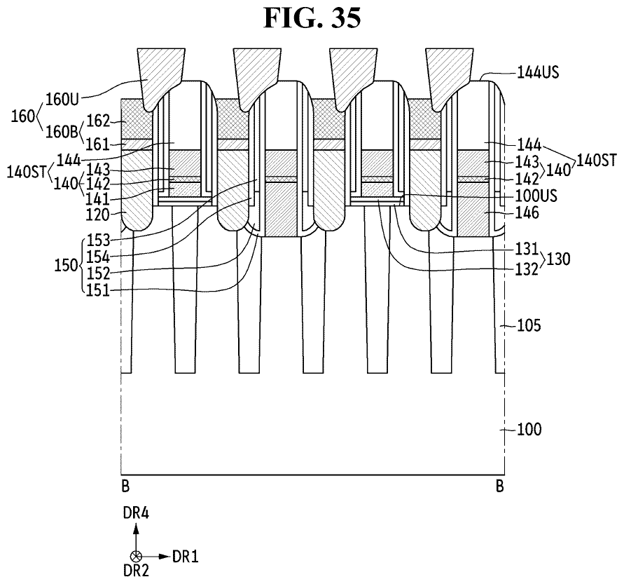

Referring to FIG. 34 and FIG. 35, the pad mask pattern 50 may be removed.

The pad mask pattern 50 may be removed so that at least a portion of the upper storage pad 160U may protrude upwardly beyond the upper surface of the cell line capping film 144US.

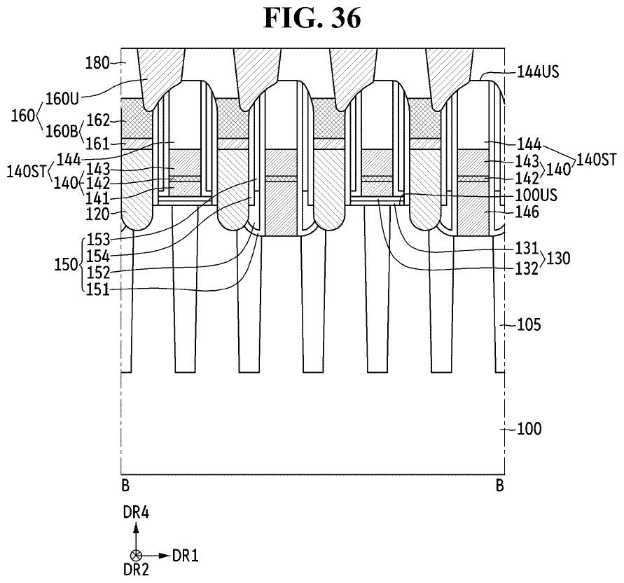

Referring to FIG. 35 and FIG. 36, the pad isolation pattern 180 may be formed on the lower storage pad 160B and the bit line structure 140ST.

The pad isolation pattern 180 may be formed around the upper storage pad 160U.

Next, referring to FIG. 18, the data storage pattern 190 may be formed on the storage pad 160.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor memory device comprising:
a substrate including an active area bounded by an element isolation film;
a bit line structure on the substrate, the bit line structure including a cell conductive line and a cell line capping film, wherein the cell line capping film extends along and on an upper surface of the cell conductive line;
storage contacts on opposing sides of the bit line structure and connected to the active area;
a storage pad on one of the storage contacts and connected to the one of the storage contacts; and
a data storage pattern on an upper surface of the cell line capping film and connected to the storage pad, and
wherein the storage pad includes an upper storage pad, and a lower storage pad between the upper storage pad and the storage contact, and
wherein a width of the upper storage pad on the upper surface of the cell line capping film increases with distance from the upper surface of the cell line capping film.

2. The semiconductor memory device of claim 1, wherein the upper storage pad includes a first portion and a second portion,
wherein the first portion of the upper storage pad is on the upper surface of the cell line capping film, and
wherein the second portion of the upper storage pad is between the first portion of the upper storage pad and the lower storage pad.

3. The semiconductor memory device of claim 1, wherein an entirety of the upper storage pad is on the upper surface of the cell line capping film and the lower storage pad.

4. The semiconductor memory device of claim 1, wherein the storage contact includes a semiconductor material,
wherein each of the upper storage pad and the lower storage pad includes a metal or a compound including a metal.

5. The semiconductor memory device of claim 1, further comprising a pad isolation pattern on a side wall of the upper storage pad,
wherein the upper storage pad includes an upper pad filling film and an upper pad silicide film, and
wherein the upper pad silicide film extends along a boundary surface between the upper pad filling film and the pad isolation pattern.

6. The semiconductor memory device of claim 5, wherein the lower storage pad includes a lower pad filling film, and a lower pad silicide film between the lower pad filling film and the storage contact.

7. The semiconductor memory device of claim 6, wherein the lower pad silicide film and the upper pad silicide film are spaced apart from each other by the lower pad filling film.

8. The semiconductor memory device of claim 5, wherein the upper storage pad is in contact with the lower storage pad, and
wherein the upper pad silicide film does not extend along a boundary surface between the upper pad filling film and the lower storage pad.

9. The semiconductor memory device of claim 5, wherein the upper pad silicide film includes a silicide of a metal included in the upper pad filling film.

10. A semiconductor memory device comprising:
a substrate including an active area bounded by an element isolation film;
a bit line structure on the substrate and including a cell conductive line and a cell line capping film stacked in a first direction, wherein the cell line capping film extends along and on an upper surface of the cell conductive line;
storage contacts on opposing sides of the bit line structure and connected to the active area;
a storage pad on one of the storage contacts and connected to the one of the storage contacts; and
a data storage pattern on an upper surface of the cell line capping film and connected to the storage pad,
wherein the storage pad includes an upper storage pad, and a lower storage pad between the upper storage pad and the storage contact,
wherein the upper storage pad includes an upper surface connected to the data storage pattern, a bottom surface in contact with the lower storage pad and the bit line structure, and a sidewall connecting the upper surface of the upper storage pad and the bottom surface of the upper storage pad to each other,
wherein the upper storage pad includes an upper pad filling film, and an upper pad silicide film, and
wherein the upper pad silicide film includes the sidewall of the upper storage pad.

11. The semiconductor memory device of claim 10, wherein the upper pad silicide film does not extend along a boundary between the upper pad filling film and the lower storage pad.

12. The semiconductor memory device of claim 10, wherein in a cross-sectional view of the semiconductor memory device, the upper pad silicide film includes a first upper pad silicide film and a second upper pad silicide film spaced apart from each other in a second direction perpendicular to the first direction, wherein the cross-sectional view is a plane comprising the first direction and the second direction, and
wherein a height in the first direction of the first upper pad silicide film is equal to a height in the first direction of the second upper pad silicide film.

13. The semiconductor memory device of claim 10, wherein in a cross-sectional view of the device, the upper pad silicide film includes a first upper pad silicide film and a second upper pad silicide film spaced apart from each other in a second direction perpendicular to the first direction, wherein the cross-sectional view is a plane comprising the first direction and the second direction,
wherein the first upper pad silicide film contacts the lower storage pad,
wherein the second upper pad silicide film contacts the bit line structure, and
wherein a height in the first direction of the first upper pad silicide film is greater than a height in the first direction of the second upper pad silicide film.

14. The semiconductor memory device of claim 10, wherein a width of the upper storage pad on the upper surface of the cell line capping film increases with distance from the upper surface of the cell line capping film.

15. The semiconductor memory device of claim 10, wherein the lower storage pad includes a lower pad filling film, and a lower pad silicide film between the lower pad filling film and the storage contact, and
wherein the lower pad silicide film is not directly connected to the upper pad silicide film.

16. The semiconductor memory device of claim 10, wherein the storage contact includes a semiconductor material, and
wherein the lower storage pad includes a metal or a compound including a metal.

17. The semiconductor memory device of claim 10, wherein the upper storage pad includes a first portion and a second portion,
wherein the first portion of the upper storage pad is on the upper surface of the cell line capping film, and
wherein the second portion of the upper storage pad is between the first portion of the upper storage pad and the lower storage pad.

18. A semiconductor memory device comprising:
a substrate including a cell area and a peripheral area around the cell area, the cell area including a cell active area bounded by a cell element isolation film;
a bit line structure on the cell area of the substrate and including a cell conductive line and a cell line capping film, wherein the cell line capping film extends along and on an upper surface of the cell conductive line;
a peripheral gate structure on the peripheral area of the substrate and including a peripheral gate conductive film;
peripheral wiring lines on the peripheral gate structure;
storage contacts connected to the cell active area;
storage pads connected to the storage contacts;
a pad isolation pattern isolating adjacent ones of the storage pads from each other; and
data storage patterns on an upper surface of the cell line capping film and connected to the storage pad,
wherein the storage pads include an upper storage pad and a lower storage pad between the upper storage pad and the storage contact,
wherein the upper storage pad includes a first portion on the upper surface of the cell line capping film and a second portion between the first portion of the upper storage pad and the lower storage pad, and
wherein a width of the first portion of the upper storage pad increases with distance from the upper surface of the cell line capping film.

19. The semiconductor memory device of claim 18, wherein the upper storage pad includes an upper pad filling film and an upper pad silicide film, and
wherein the upper pad silicide film extends along a boundary surface between the upper pad filling film and the pad isolation pattern.

20. The semiconductor memory device of claim 18, wherein a width of the peripheral wiring line increases with distance from the peripheral gate conductive film,
wherein the peripheral wiring line includes a peripheral wiring filling film and a peripheral wiring silicide film, and
wherein the peripheral wiring silicide film includes a side wall of the peripheral wiring line.
